(19) United States
(12) Patent Application Publication
(10) Pub. No.: US 2026/0126499 A1
(43) Pub. Date: May 7, 2026

(54) METHOD AND SYSTEM FOR AUTOMATICALLY CORRECTING POWER QUALITY SENSOR CONNECTIONS

(71) Applicant: POWER MONITORS, INC., Mt. Crawford, VA (US)

(72) Inventors: David HORNING, Mt. Crawford, VA (US); Christopher Fisher MULLINS, Mt. Crawford, VA (US)

(21) Appl. No.: 19/377,584

(22) Filed: Nov. 3, 2025

Related U.S. Application Data
(60) Provisional application No. 63/715,182, filed on Nov. 1, 2024.

(51) Int. Cl. G01R 31/42; G01R 19/165; G01R 19/25; G01R 31/54; H02J 3/00; H02J 3/38

(52) U.S. Cl. CPC G01R 31/42; G01R 19/16547; G01R 19/2509; G01R 19/2513; G01R 31/54; H02J 3/0012; H02J 3/381; H02J 2101/22; H02J 2103/30

(57) ABSTRACT

A process in device may include measuring an electrical parameter of a monitored element through at least one connection with at least one transducer, determining whether the at least one connection to the monitored element is correct based on the electrical parameter with at least one processor, and outputting an error and potential fixes when the at least one connection to the monitored element is not correct with the at least one processor, and/or correcting electrical parameter data when the at least one connection to the monitored element is not correct with the at least one processor. The electrical parameter may include at least one of the following: voltage, current, phase, and/or polarity. Other embodiments of this aspect include corresponding computer systems, apparatus, and computer programs recorded on one or more computer storage devices, each configured to perform the actions of the methods.

### CROSS-REFERENCE TO RELATED APPLICATIONS

This application claims the benefit from U.S. Provisional Application No. 63/715,182 filed on Nov. 1, 2024, which is hereby incorporated by reference in its entirety for all purposes as if fully set forth herein.

### FIELD OF THE DISCLOSURE

The disclosure relates to a method for automatically correcting power quality sensor connections. The disclosure further relates to a system for automatically correcting power quality sensor connections. The disclosure relates to a method for automatically detecting power quality sensor connections. The disclosure further relates to a system for automatically detecting power quality sensor connections.

### BACKGROUND

Power quality sensors and recorders are essential tools for electric utilities to diagnose and track voltage quality and electrical problems within their own network and for their customers. To make valid power quality measurements, proper connection of the device is essential. Common metrics such as real and reactive power, power factor, etc. rely on the correct polarity and phasing of voltage and current probes. Analysis of voltage sag, direction, classification, transients, and/or the like also depend on the correct polarity and matching of voltage and current phases for all device inputs. Consequently, correct device hookup by the field technician is essential for a power quality analysis.

In many cases the only practical monitoring point is inside an existing enclosure such as a revenue meter base, Current Transformer (CT) cabinet, capacitor controller, etc., which contains the necessary voltage and current signals. In these situations, wiring can be confusing with unlabeled or mismarked conductors, and no clear indication of phasing in a polyphase system. Correct CT polarity can be difficult to determine when connecting a PQ recorder to metering CTs, and voltage phasing may not be clear when connecting to existing PTs (potential transformers). Further, field technicians commonly make installation mistakes when sent to the field by engineers, where the engineer must rely on the technician to interpret the situation on their own.

### SUMMARY OF THE DISCLOSURE

The foregoing needs are met, to a great extent, by the disclosure.

In one general aspect, a process may include measuring an electrical parameter of a monitored element through at least one connection with at least one transducer. The process may also include determining whether the at least one connection to the monitored element is correct based on the electrical parameter with at least one processor. The process may furthermore include outputting an error and potential fixes when the at least one connection to the monitored element is not correct with the at least one processor; and/or correcting electrical parameter data when the at least one connection to the monitored element is not correct with the at least one processor. The process may in addition include where the electrical parameter may include at least one of the following: voltage, current, phase, and/or polarity. Other embodiments of this aspect include corresponding computer systems, apparatus, and computer programs recorded on one or more computer storage devices, each configured to perform the actions of the methods.

In one general aspect, an apparatus may include at least one transducer configured to measure an electrical parameter of a monitored element through at least one connection. The apparatus may also include at least one processor configured and/or operable to determine whether the at least one connection to the monitored element is correct based on the electrical parameter. The apparatus may furthermore include the at least one processor configured and/or operable to output an error and potential fixes when the at least one connection to the monitored element is not correct; and /r the at least one processor configured and/or operable to correct data when the at least one connection to the monitored element is not correct. The apparatus may in addition include where the electrical parameter may include at least one of the following: voltage, current, phase, and/or polarity. Other embodiments of this aspect include corresponding computer systems, apparatus, and computer programs recorded on one or more computer storage devices, each configured to perform the actions of the methods.

The disclosure below solves these problems with a mechanism, system, and/or process to automatically identify common hookup errors, and optionally have the device correct for them in the device operation, before power quality metrics and recorded data is derived from them.

A method for automatically identifying and/or correcting common power quality recorder hookup mistakes is described here. The disclosure may include an algorithm for detecting hookup problems and/or automatically correcting for these at a low level in the device operation, such that all downstream operations on the data are unaffected by the original hookup mistake.

The method consists of two phases. The first phase occurs before a power quality recording, during or just after the installer is connecting the voltage and current inputs to the recorder. Near the end of this process the device attempts to detect the most common connection mistakes. The user may be prompted via smart phone, tablet, or other application that a connection problem is detected, and suggest a solution. Optionally, the device may automatically apply software corrections to the input signals that fix the connection problems, so that the recorded data is not affected by the mistakes.

The second phase occurs during the recording process. Signal corrections are made on a continuous basis to undo the hookup errors, in such a way that the data is unaffected. In addition, the corrections that were made are logged in the recording so that a record is preserved.

These hookup mistakes may persist over multiple recordings if the device is left in the field. The device may be configured to keep the corrections through multiple recordings in this case, or in permanent installations.

### Theory of Operation

A typical PQ monitor continuously samples one or more voltage and current inputs through voltage and current transducers. The current transducers are usually CTs, either iron-core or Rogowksi-based. The voltage inputs are typically connected directly to 600 VAC or lower terminals, sometimes through Potential Transformers (PTs). In the US these are typically 60 Hz AC signals. In a 3-phase circuit, there are 3 voltage and current inputs, and optionally a 4^{th} input sometimes used for neutral or ground measurements.

There are a few common types of hookup mistakes made in the field. The simplest is a “backwards CT”. Each CT has a polarity associated with it, typically indicated with an arrow on the CT element. This arrow typically is supposed to point towards the load, away from the power source. When the CT polarity is correct, the AC current measured is in phase with the corresponding AC voltage signal, and correct power flow direction may be measured. If the CT physical orientation is reversed with respect to current-carrying conductor, the raw current waveform will be inverted, resulting in power flow of the opposite mathematic sign (e.g. negative power instead of positive power). Other power quality metrics may also be affected by the inverted current signal. In a 3-phase circuit, any or all of the 3 CTs around current-carrying conductors may be installed in the correct, or inverted polarity.

Another type of connection mistake is mis-matching the voltage and current inputs. A PQ recorder typically has 3 or more voltage and current inputs. In this description the inputs are labeled with channel number, e.g. channel 1, 2, or 3 voltage and channel 1, 2 or 3 current. In a correct installation, the same channel number is used for the same phase of voltage and current. E.g. in a 3-phase circuit, with phases A, B, and C, channel 1 voltage input should be connected to phase A voltage, channel 1 current input's CT should be clamped around the phase A current conductor (with the correct polarity orientation), phase B with channel 2, etc. The CT phases are commonly “swapped”, or “rolled’. With swapped CTs, there is a mismatch of voltage and current phases on two channels, e.g. channel 1 voltage input is connected to phase A voltage, but the channel 1 CT is clamped around the phase B conductor, and channel 2 voltage input is connected to phase B voltage but the channel 2 CT is clamped around the phase A conductor. Another possibility is swapped CTs between B and C phases, or A and C. With “rolled” CTs, all three CTs are mismatched with the voltages, e.g. channels 1,2,3 voltage inputs are connected to voltage phases A, B, C, but channels 1,2,3 current inputs are connected to phases B, C, A.

Another type of connection mistake is incorrect phase rotation. Voltage and current CTs may be matched on a per-channel basis, but the overall phasing is not correct. In a 3-phase circuit there are two phase rotations, often denoted ABC and ACB. In some cases, it doesn't matter if the recorder hookup is rotated, as long as the voltage and current inputs are matched individually on a per-phase basis, and the CTs are correctly oriented. However, in some cases correct phase rotation is desired. Each of these hookup mistakes may occur in combination, e.g. inverted CT and mismatched phases between voltage and current.

Each of these hookup mistakes may be corrected by the device at an early point in the internal signal processing chain, in such a way that all subsequent calculations are unaffected. A backwards CT is fixed by mathematically inverting the sampled waveform, as this is equivalent to changing the physical polarity of the CT itself. The mapping of sampled inputs on channels 1,2,3, etc. to logical phases is arbitrary in the device and may be remapped to swap channels around. In general, a physical-to-logical channel mapping allows for any assignment of physical channel inputs to logical channel outputs that feed all subsequent processing.

For example, if the channel 2 current input is actually connected to phase C current, the physical channel 2 sampled data may be assigned to the logical channel 3 slot, thus matching it with the phase C voltage connected to voltage channel 3. Rolled phases are also corrected exactly with a channel map. The mathematical inversion and channel mapping are independent and can be performed as needed to correct for any combination of hookup mistakes described above.

The channel and inversion mapping may be preserved in the recorded data to keep a record of any correction. With live data streaming, the corrections may be sent with the live data. For example, a user connected via Wi-Fi to a device with a smartphone or tablet may view live waveforms or vector diagrams with the corrected data, and since the correction parameters are sent with the data, the corrections may be undone in the UI to show the user the raw waveforms or diagrams without corrections applied.

A novel aspect of the disclosure is the automatic detection of hookup problems. One method is to minimize the total phase angle difference across all three phases, as described below.

In a 3-phase power circuit, the utility supplies three voltages at a nominal RMS voltage and phase angle at 60 Hz, typically labeled A, B, and C. The voltage waveforms may have other frequency components present, so the 60 Hz component is calculated in real time by the device, resulting in a magnitude and phase angle reading (or phasor) for each of the three voltage inputs. In a normal 3 phase wye or delta circuit, each voltage magnitude is equal, and the phase angles are 120 degrees apart from each other (e.g. 277 V, 0 degrees for phase A, 277 V, −120 degrees for phase B, and 277 V, +120 degrees for phase C). Phase A voltage is normally the phase angle reference, and set to zero degrees. Similarly the 60 Hz component of the three current inputs is also computed, with a resulting magnitude and phase angle. The method given in IEEE 519 for computing the 60 Hz phasor over a 200 ms period may be used, although other methods are possible.

The current magnitudes are used to validate the possibility of correcting hookup errors. If the magnitude is close to zero, then possibly there is no current flow, or too little to detect a hookup problem. If the magnitude is above a certain threshold, e.g. 1% of full scale, then the method can proceed.

In an ideal polyphase system, the phase angle difference between the voltage and corresponding current phasor is zero, or in a 3-phase delta, 30 degrees. Any additional phase angle shift is typically due to inductive or capacitive loads. This additional phase angle shift reduces power factor and overall efficiency and is generally corrected with other devices to minimize system losses. Consequently, the phase angle difference between voltage and current phasors is generally close to the ideal.

The hookup errors described above are detectable by the increase in phase angle difference. For example, an inverted CT will introduce an 180 degree phase angle shift. If two CTs are swapped (e.g. phase A's CT on phase B, and vice versa), a 120 degree phase angle shift will be introduced on two channels. Every possible hookup variation involving any combination of inverted CTs, swapped CT channels, or rolled CTs introduces increased phase angle shifts to one or more channels. The sum of the absolute values of the 60 Hz phase angle differences between each voltage and current channel is thus a metric for hookup quality. The device can simulate the effect of inverting a CT, swapping CT channels, or rolling all three CTs by adding or subtracting 180 or 120 degrees appropriately. By enumerating through all possible unique combinations of hookup fixes, finding the sum of the absolute value of phase angle differences for all 3 inputs, the optimal hookup fix is determined. The combination with the lowest total phase angle difference is the “correct” hookup, and whatever combination of CT inversions, swaps, and rolls produced that lowest total is the correct fix to apply.

This technique relies on the fact that real phase angle differences between a typical 3 phase voltage and current phase are less than 180 or 120 degrees. To identify phase rotation, symmetrical component calculations may be used on the voltage inputs. A larger negative than positive sequence voltage indicates the opposite phase rotation. Channel mapping may be used to correct this.

When the device identifies that a correction is needed (by finding a correction with a lower total phase angle difference than the uncorrected readings), the user can be prompted with the suggested corrections. The user may physically re-arrange CTs as needed to correct the hookup, or allow the device to apply software corrections by inverting current inputs, or remapping physical to logical channels as needed.

The recorder will need to apply the corrections carefully. For example, any residual DC offsets must be subtracted or accounted for, before a mathematical inversion. If physical to logical channel mapping is performed, physical channel calibration constants inside the device (e.g. gain or offsets) must be applied to the physical channel, while external correction factors (e.g. turns ratios, frequency compensation, etc.) that are specific to external transducers may need to be applied to the logical channel.

One preferred embodiment for this method is in a portable PQ recorder. In this embodiment the recorder is installed in the field, and during installation the recorder powers on and begins a pre-recording check (the “countdown” period). During the countdown, the installer can connect to the device and view live readings, identify any hookup issues, and correct them. If the installer does not do that, then near the end of the countdown, the recorder uses the method described above to identify an incorrect hookup, notify the user, and optionally automatically apply a correction. If a correction is applied, it is performed before the recording starts, and persists throughout the recording. The correction itself also is logged in the recording.

For extended monitoring where multiple recordings are performed, or permanent installations, the device may be configured to keep a hookup correction in place permanently.

A correction may also be sent to a recorder manually, overriding any automatic correction. This may be desired in situations where it's not possible for the recorder to correctly detect the problem, or if the physical connections have changed.

In another embodiment, the device is not a recorder, but a sensor that streams data to another collection device. The corrections are still detected and applied by the device, but the device itself is a sensor, not a recorder.

In another embodiment, the method is applied to voltage and current waveform data that has already been collected. For example, a continuous waveform collection system may record 3 phase voltage and current samples without any corrections. Offline analysis may be performed later to determine a hookup problem and automatically determine corrections as per the method above. These corrections could be used to re-save the data in a corrected form, or the corrections could be stored for use later on the fly when the data is actually analyzed.

In another embodiment, a power quality recording without corrections could be analyzed with software in the traditional fashion, but with the addition of the method above to detect and correct the recorded data where possible. Some recorded data may not be correctable (e.g. recorded real power), but other data types may be. The software could also warn the user that an incorrect hookup was detected, and some data may not be correct.

### BRIEF DESCRIPTION OF THE DRAWINGS

FIG. 1 illustrates a system according to aspects of the disclosure.

FIG. 2 illustrates a data collection unit according to aspects of the disclosure.

FIG. 3, FIG. 4, FIG. 5, FIG. 6, FIG. 7, FIG. 8, FIG. 9, FIG. 10, FIG. 11, FIG. 12, FIG. 13, FIG. 14, and FIG. 15 illustrate implementations of a device having outputs-interfaces according to aspects of the disclosure.

FIG. 16 illustrates a process according to aspects of the disclosure.

FIG. 17 illustrates a data concentrator according to aspects of the disclosure.

FIG. 18 illustrates further aspects of a data collection unit according to aspects of the disclosure.

FIG. 19 illustrates an exemplary implementation of a cloud-based server system according to aspects of the disclosure.

FIG. 20 illustrates a process for electric power data collection and analysis according to aspects of the disclosure.

### DETAILED DESCRIPTION

The disclosure will now be described with reference to the drawing figures, in which like reference numerals refer to like parts throughout.

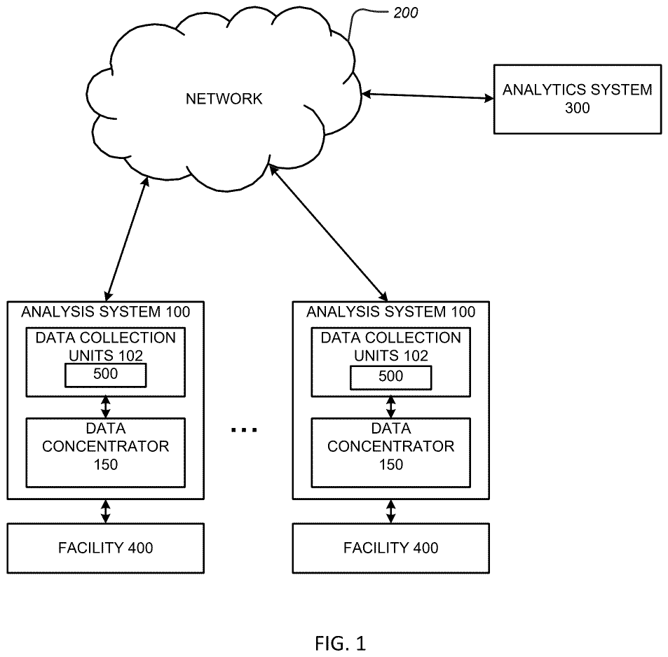

FIG. 1 illustrates a system according to aspects of the disclosure.

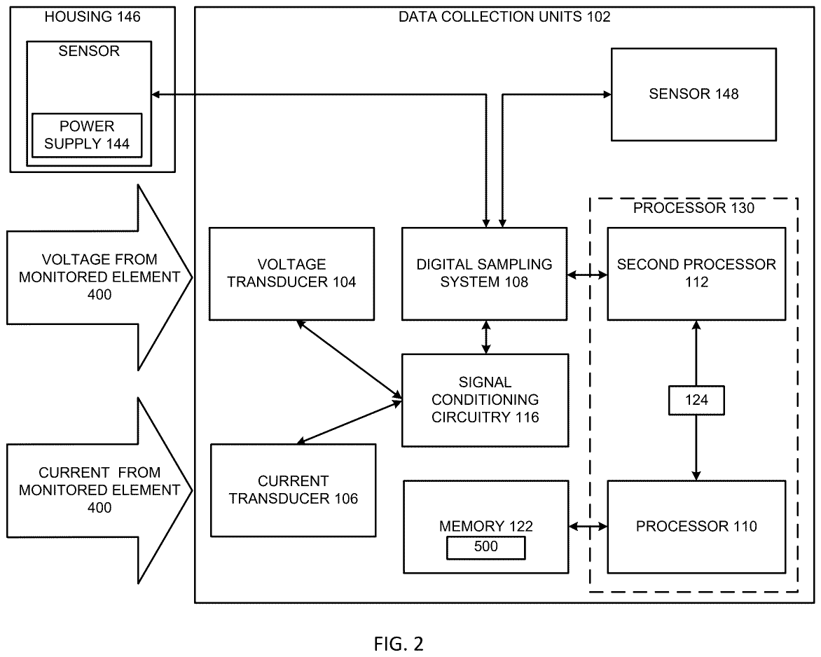

FIG. 2 illustrates a data collection unit according to aspects of the disclosure.

The disclosure is directed to an electric power data collection and analysis system 100 implementing a diagnostic and/or data correction process 500. In aspects, the electric power data collection and analysis system 100 may include one or more data collection units 102 and/or one or more implementations of a data concentrator 150. Additionally, the data concentrator 150 and/or the electric power data collection and analysis system 100 may be configured to send the data over a network 200 on a communication channel as defined herein to a data lake or a cloud-based analytics system 300. The electric power data collection and analysis system 100 may be configured to collect and analyze power data for a monitored element 400.

In aspects, the diagnostic and/or data correction process 500 may be implemented by the electric power data collection and analysis system 100, the one or more data collection units 102, the data concentrator 150, the cloud-based analytics system 300, another device, another system, and/or the like. In aspects, the electric power data collection and analysis system 100 may be configured and/or operable to implement the diagnostic and/or data correction process 500 as described herein.

In aspects, the diagnostic and/or data correction process 500 may be implemented by a processor of the one or more data collection units 102, such as the processor 110 and/or the second processor 112 illustrated in FIG. 2. Further, the diagnostic and/or data correction process 500 may be configured as an algorithm and/or program executed by the processor of the one or more data collection units 102. In this regard, the program implementing the diagnostic and/or data correction process 500 may be stored in a memory of the one or more data collection units 102, such as the memory 122. In aspects, the one or more data collection units 102 may be configured and/or operable to implement the diagnostic and/or data correction process 500 as described herein.

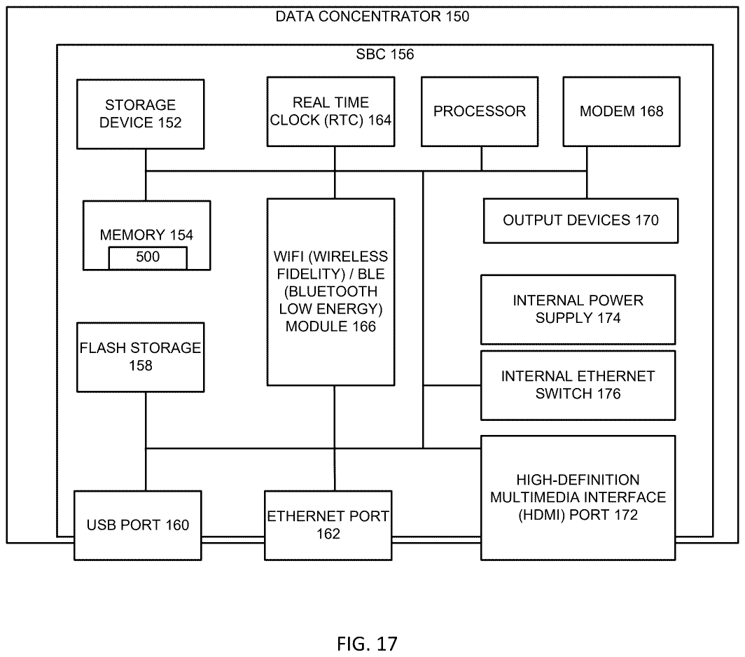

In aspects, the diagnostic and/or data correction process 500 may be implemented by a processor of the data concentrator 150 illustrated in FIG. 17. In this regard, the program implementing the diagnostic and/or data correction process 500 may be stored in a memory of the data concentrator 150, such as the memory 154. In aspects, the data concentrator 150 may be configured and/or operable to implement the diagnostic and/or data correction process 500 as described herein.

In aspects, the diagnostic and/or data correction process 500 may be implemented by a processor of the cloud-based analytics system 300, such as the data server 450 illustrated in FIG. 19. In this regard, the program implementing the diagnostic and/or data correction process 500 may be stored in a memory of the cloud-based analytics system 300. In aspects, the cloud-based analytics system 300 may be configured and/or operable to implement the diagnostic and/or data correction process 500 as described herein.

The monitored element 400 may be an electrical substation, a solar farm, a wind farm, a Distributed Energy Resource (DER), a portion of a utility transmission infrastructure, a portion of a utility generation infrastructure, one or more circuits, one or more machines, one or more components, and/or the like. The electric power data collection and analysis system 100 may include two core components.

In aspects, the one or more data collection units 102 may include at least one transducer configured to measure one or more electrical parameters associated with the monitored element 400 such as voltage, current, power, and/or the like. With reference to FIG. 2, the one or more data collection units 102 may include a voltage transducer 104, a current transducer 106, a sampling system 108 that may include an A/D (analog to digital) converter, and/or the like.

In aspects, the electric power data collection and analysis system 100 and/or the one or more data collection units 102 may continuously sample one or more voltage and current inputs from the monitored element 400 through voltage and current transducers, such as the voltage transducer 104 and/or the current transducer 106. In aspects, the current transducer 106 may be implemented by CTs, that may be iron-core or Rogowksi-based. The voltage inputs from the monitored element 400 may be connected directly to 600 VAC or lower terminals, sometimes through Potential Transformers (PTs). In the United States, these may typically be 60 Hz AC signals. In a 3-phase circuit, there may be 3 voltage and current inputs, and optionally a 4^{th} input sometimes used for neutral or ground measurements.

In aspects, the diagnostic and/or data correction process 500 may be configured and/or operable to address common types of hookup mistakes made in the field. The simplest is a “backwards CT”. Each CT has a polarity associated with it, typically indicated with an arrow on the CT element of the electric power data collection and analysis system 100, the one or more data collection units 102, the data concentrator 150, and/or the like. This arrow typically is supposed to point towards the load, away from the power source.

When the CT polarity is correct, the AC current measured by the electric power data collection and analysis system 100, the one or more data collection units 102, and/or the data concentrator 150 is in phase with the corresponding AC voltage signal, and correct power flow direction may be measured. If the CT physical orientation is reversed with respect to current-carrying conductor, the raw current waveform will be inverted, resulting in power flow of the opposite mathematic sign (e.g. negative power instead of positive power). Other power quality metrics may also be affected by the inverted current signal. In a 3-phase circuit, any or all of the 3 CTs around current-carrying conductors may be installed in the correct, or inverted polarity.

Another type of connection mistake is mis-matching the voltage and current inputs. A PQ recorder typically has 3 or more voltage and current inputs. In this description the inputs are labeled with channel number, e.g. channel 1, 2, or 3 voltage and channel 1, 2 or 3 current. In a correct installation, the same channel number is used for the same phase of voltage and current. E.g. in a 3-phase circuit, with phases A, B, and C, channel 1 voltage input should be connected to phase A voltage, channel 1 current input's CT should be clamped around the phase A current conductor (with the correct polarity orientation), phase B with channel 2, etc. The CT phases are commonly “swapped”, “rolled”, and/or the like.

With swapped CTs, there is a mismatch of voltage and current phases on two channels, e.g. channel 1 voltage input is connected to phase A voltage, but the channel 1 CT is clamped around the phase B conductor, and channel 2 voltage input is connected to phase B voltage but the channel 2 CT is clamped around the phase A conductor. Another possibility is swapped CTs between B and C phases, or A and C. With “rolled” CTs, all three CTs are mismatched with the voltages, e.g. channels 1,2,3 voltage inputs are connected to voltage phases A, B, C, but channels 1,2,3 current inputs are connected to phases B, C, A.

In aspects, the diagnostic and/or data correction process 500 may be configured and/or operable to address another type of connection mistake, which is incorrect phase rotation. In this regard, the voltage transducer 104 and the current transducer 106 may be matched on a per-channel basis, but the overall phasing is not correct. In a 3-phase circuit there are two phase rotations, often denoted ABC and ACB. In some cases, it does not matter if the recorder hookup is rotated, as long as the voltage and current inputs are matched individually on a per-phase basis, and the current transducer 106 are correctly oriented. However, in some cases correct phase rotation is desired.

Each of these hookup mistakes may occur in combination, e.g. inverted CT and mismatched phases between voltage and current. Additionally, there may be further hookup mistakes, such as poor connection, failed connection, and/or the like.

Each of these hookup mistakes may be corrected by the device at an early point in the internal signal processing chain, in such a way that all subsequent calculations are unaffected. In particular, these hookup mistakes may be corrected by the electric power data collection and analysis system 100, the one or more data collection units 102, and/or the data concentrator 150 through implementation of the diagnostic and/or data correction process 500 at an early point in the internal signal processing chain, in such a way that all subsequent calculations are unaffected.

In particular, these hookup mistakes may be determined and communicated to a user by the diagnostic and/or data correction process 500 and displayed on a graphical user interface of a device for correction by the user. In this regard, the user may be prompted via smart phone, tablet, or other application that a connection problem is detected, and suggest a solution.

In aspects, the diagnostic and/or data correction process 500 may be configured and/or operable such that a backwards CT is fixed by mathematically inverting the sampled waveform, as this is equivalent to changing the physical polarity of the CT itself.

The mapping of sampled inputs on channels 1, 2, 3, etc. to logical phases is arbitrary in the device and may be remapped to swap channels around by the diagnostic and/or data correction process 500. In general, a physical-to-logical channel mapping implemented by the diagnostic and/or data correction process 500 may be configured and/or operable such that it allows for any assignment of physical channel inputs to logical channel outputs that feed all subsequent processing. For example, if the channel 2 current input is actually connected to phase C current, the physical channel 2 sampled data may be assigned to the logical channel 3 slot by the diagnostic and/or data correction process 500, thus matching it with the phase C voltage connected to voltage channel 3. Rolled phases are also corrected exactly with a channel map.

The mathematical inversion and channel mapping are independent and can be performed by the diagnostic and/or data correction process 500 as needed to correct for any combination of hookup mistakes described above.

The channel and inversion mapping by the diagnostic and/or data correction process 500 may be preserved in the recorded data to keep a record of any correction. With live data streaming, the corrections by the diagnostic and/or data correction process 500 may be sent with the live data. For example, a user connected via Wi-Fi to a device with a smartphone or tablet may view live waveforms or vector diagrams with the corrected data, and since the correction parameters are sent with the data, the corrections may be undone in the UI to show the user the raw waveforms or diagrams without corrections applied.

A novel aspect of the diagnostic and/or data correction process 500 may be the automatic detection of hookup problems. One method is to minimize the total phase angle difference across all three phases, as described below.

In a 3-phase power circuit, the monitored element 400, such as a utility, supplies three voltages at a nominal RMS voltage and phase angle at 60 Hz, typically labeled A, B, and C. The voltage waveforms may have other frequency components present, so the 60 Hz component is calculated in real time by the device, resulting in a magnitude and phase angle reading (or phasor) for each of the three voltage inputs. In a normal 3 phase wye or delta circuit, each voltage magnitude is equal, and the phase angles are 120 degrees apart from each other (e.g. 277 V, 0 degrees for phase A, 277 V, −120 degrees for phase B, and 277 V, +120 degrees for phase C). Phase A voltage is normally the phase angle reference, and set to zero degrees. Similarly the 60 Hz component of the three current inputs is also computed, with a resulting magnitude and phase angle. The method given in IEEE 519 for computing the 60 Hz phasor over a 200 ms period may be used, although other methods are possible.

In aspects, the diagnostic and/or data correction process 500 may be configured and/or operable such that the current magnitudes are used to validate the possibility of correcting hookup errors. If the magnitude is close to zero, then possibly there is no current flow, or too little to detect a hookup problem. If the magnitude is above a certain threshold, e.g. 1% of full scale, then the method can proceed.

In an ideal polyphase system, the phase angle difference between the voltage and corresponding current phasor is zero, or in a 3-phase delta, 30 degrees. Any additional phase angle shift is typically due to inductive or capacitive loads. This additional phase angle shift reduces power factor and overall efficiency and is generally corrected with other devices to minimize system losses. Consequently, the phase angle difference between voltage and current phasors is generally close to the ideal.

The hookup errors described above are detectable by the diagnostic and/or data correction process 500 based on the increase in phase angle difference. For example, an inverted CT will introduce an 180 degree phase angle shift. If two CTs are swapped (e.g. phase A's CT on phase B, and vice versa), a 120 degree phase angle shift will be introduced on two channels. Every possible hookup variation involving any combination of inverted CTs, swapped CT channels, or rolled CTs introduces increased phase angle shifts to one or more channels. The sum of the absolute values of the 60 Hz phase angle differences between each voltage and current channel is thus a metric for hookup quality.

The electric power data collection and analysis system 100, the one or more data collection units 102, and/or the data concentrator 150 can implement the diagnostic and/or data correction process 500 to simulate the effect of inverting a CT, swapping CT channels, or rolling all three CTs by adding or subtracting 180 or 120 degrees appropriately. By enumerating through all possible unique combinations of hookup fixes, finding the sum of the absolute value of phase angle differences for all 3 inputs, the optimal hookup fix is determined by the diagnostic and/or data correction process 500. The combination with the lowest total phase angle difference may be determined by the diagnostic and/or data correction process 500 as the “correct” hookup, and whatever combination of CT inversions, swaps, and rolls produced that lowest total is the correct fix to apply.

This technique implemented by the diagnostic and/or data correction process 500 may rely on the fact that real phase angle differences between a typical 3 phase voltage and current phase are less than 180 or 120 degrees.

To identify phase rotation, symmetrical component calculations may be used on the voltage inputs by the diagnostic and/or data correction process 500. A larger negative than positive sequence voltage detected by the electric power data collection and analysis system 100, the one or more data collection units 102 and/or the data concentrator 150 implementing the diagnostic and/or data correction process 500 may indicate the opposite phase rotation. Channel mapping may be implemented by the diagnostic and/or data correction process 500 to correct this.

When the electric power data collection and analysis system 100, the one or more data collection units 102 and/or the data concentrator 150 implementing the diagnostic and/or data correction process 500 identifies that a correction is needed (by finding a correction with a lower total phase angle difference than the uncorrected readings), the user can be prompted with the suggested corrections. The user may physically re-arrange CTs as needed to correct the hookup, or allow the electric power data collection and analysis system 100, the one or more data collection units 102 and/or the data concentrator 150 implementing the diagnostic and/or data correction process 500 may apply software corrections by inverting current inputs, or remapping physical to logical channels as needed.

The electric power data collection and analysis system 100, the one or more data collection units 102 and/or the data concentrator 150 implementing the diagnostic and/or data correction process 500 will need to apply the corrections carefully. For example, any residual DC offsets must be subtracted or accounted for, before a mathematical inversion. If physical to logical channel mapping is performed, physical channel calibration constants inside the device (e.g. gain or offsets) must be applied to the physical channel, while external correction factors (e.g. turns ratios, frequency compensation, etc.) that are specific to external transducers may need to be applied to the logical channel.

One aspect for this method is in a portable PQ recorder. In this regard, the portable PQ recorder may be implemented with some or all of the features of the electric power data collection and analysis system 100, the one or more data collection units 102 and/or the data concentrator 150. Additionally, the portable PQ recorder may implement the diagnostic and/or data correction process 500. In this embodiment the recorder is installed in the field, and during installation the recorder powers on and begins a pre-recording check (the “countdown” period). During the countdown, the installer can connect to the device and view live readings, identify any hookup issues, and correct them. If the installer does not do that, then near the end of the countdown, the recorder uses the diagnostic and/or data correction process 500 described above to identify an incorrect hookup, notify the user, and optionally automatically apply a correction. If a correction is applied, it is performed before the recording starts, and persists throughout the recording. The correction itself also is logged in the recording.

For extended monitoring where multiple recordings are performed, or permanent installations, the electric power data collection and analysis system 100, the one or more data collection units 102 and/or the data concentrator 150 implementing the diagnostic and/or data correction process 500 may be configured to keep a hookup correction in place permanently.

A correction may also be sent to a recorder manually, overriding any automatic correction. This may be desired in situations where it is not possible for the recorder to correctly detect the problem, or if the physical connections have changed.

In another embodiment, the device is not a recorder, but a sensor that streams data to another collection device. In aspects, the sensor may be any one of the sensors as described herein that may be implemented by the one or more data collection units 102. The sensor may implement a processor and/or memory for implementation of the diagnostic and/or data correction process 500 such that errors are still detected and corrections applied by the device, but the device itself is a sensor, not a recorder.

In another embodiment, the diagnostic and/or data correction process 500 may be applied to voltage and current waveform data that has already been collected by the electric power data collection and analysis system 100. For example, a continuous waveform collection system may record 3 phase voltage and current samples without any corrections. Offline analysis may be performed later to determine a hookup problem and automatically determine corrections as per the method above.

For example, the cloud-based analytics system 300 may implement the diagnostic and/or data correction process 500 so that analysis may be performed later to determine a hookup problem and automatically determine corrections. These corrections could be used to re-save the data in a corrected form, or the corrections could be stored for use later on the fly when the data is actually analyzed. In aspects, this may be implemented by the cloud-based analytics system 300.

In another embodiment, a power quality recording without corrections could be analyzed with software in the traditional fashion, but with the addition of the diagnostic and/or data correction process 500 above to detect and correct the recorded data where possible. Some recorded data may not be correctable (e.g. recorded real power), but other data types may be. The diagnostic and/or data correction process 500 may be configured and/or operable to also warn the user that an incorrect hookup was detected, and some data may not be correct.

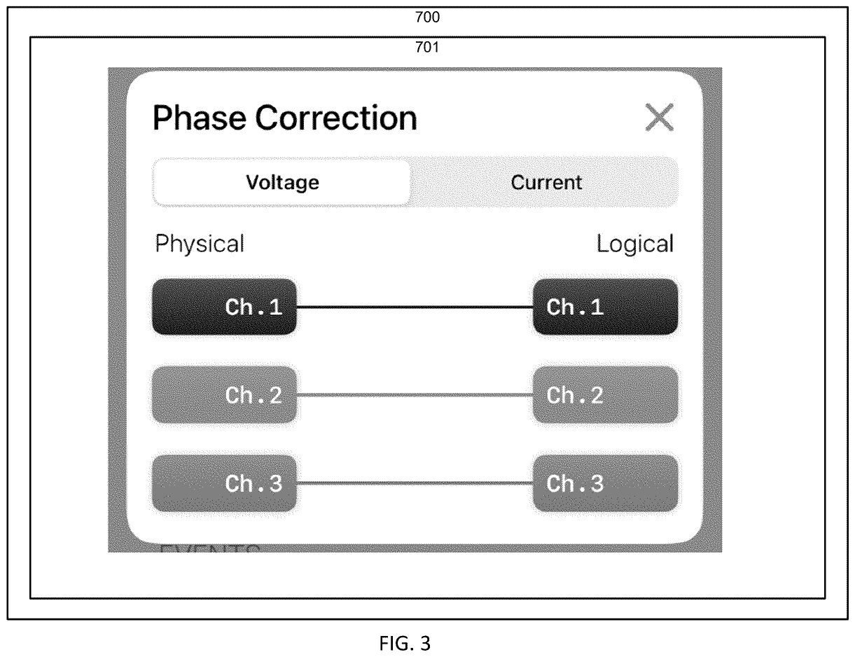

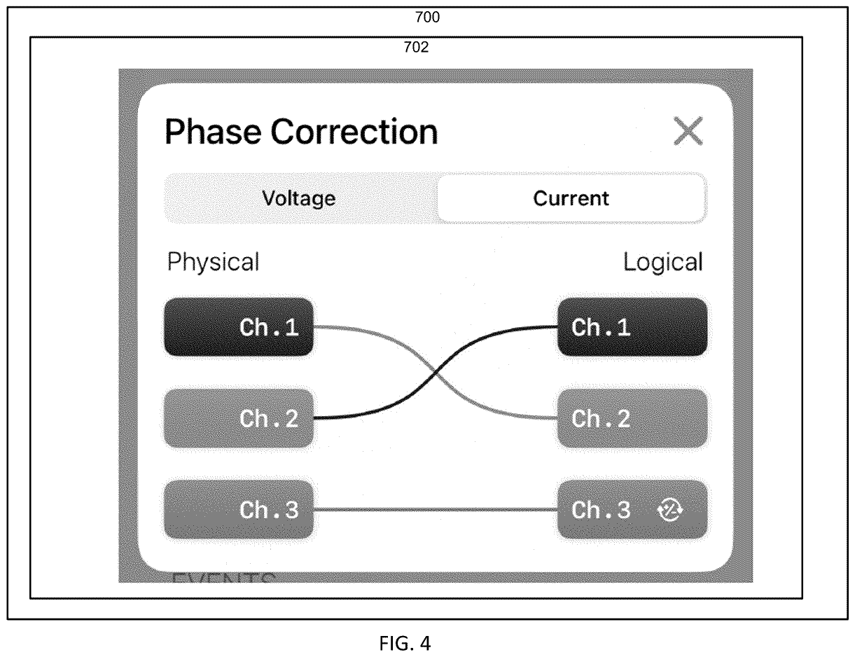

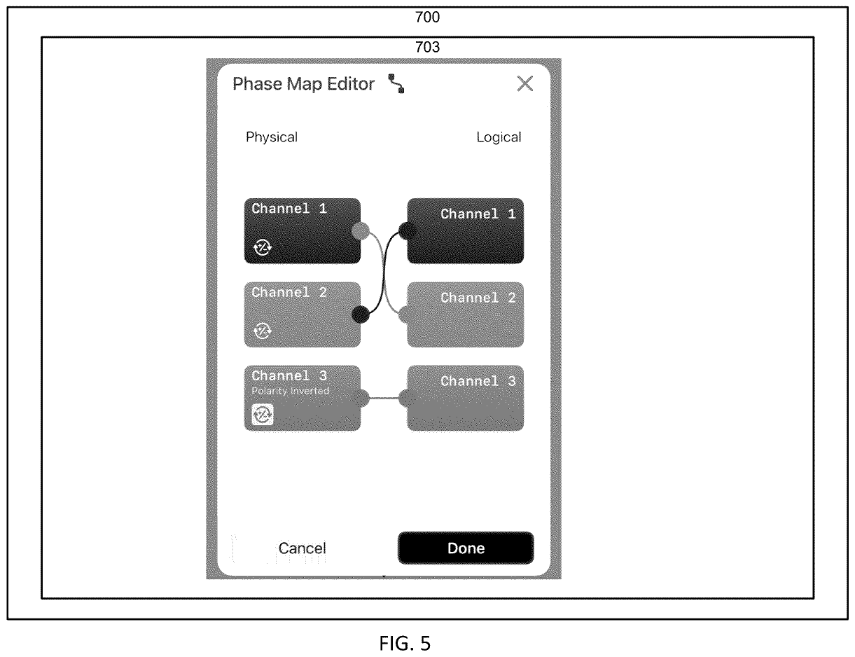

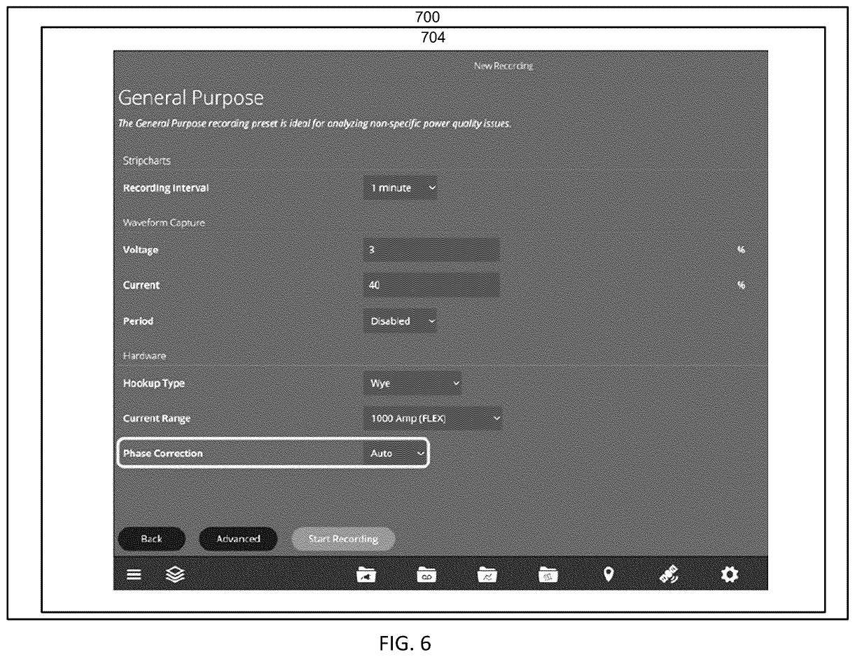

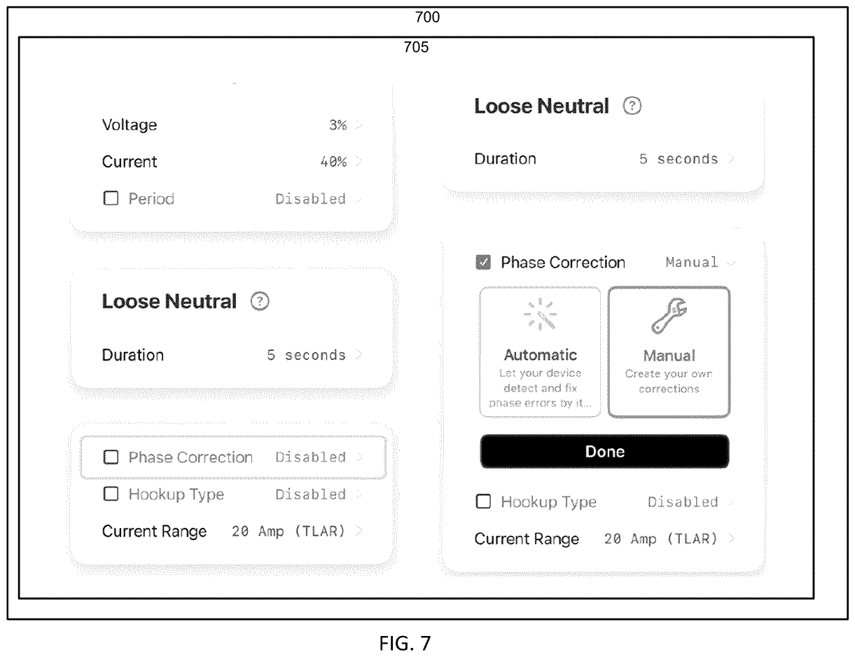

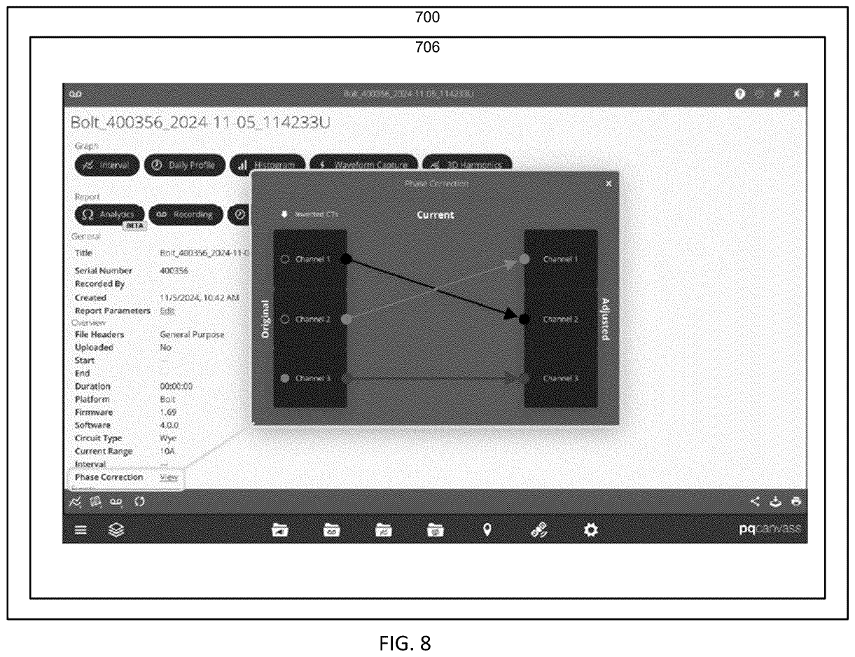

FIG. 3, FIG. 4, FIG. 5, FIG. 6, FIG. 7, FIG. 8, FIG. 9, FIG. 10, FIG. 11, FIG. 12, FIG. 13, FIG. 14, and FIG. 15 illustrate implementations of a device having outputs-interfaces according to aspects of the disclosure.

In aspects illustrated in FIG. 3-15, a device 700 may be a device that includes one or more of the electric power data collection and analysis system 100, the one or more data collection units 102, the data concentrator 150, the cloud-based analytics system 300, another device, another system, and/or the like. In this regard, some aspects described herein may be implemented by one implementation of the device 700 and other aspects described herein may be implemented by another implementation of the device 700.

In aspects, the device 700 may include a human machine interface 720. The human machine interface 720 may be a display, a touchscreen display, an output device, a printer, a screen, and/or the like.

For example, an implementation of the device 700 may be the one or more data collection units 102 and another implementation of the device 700 may be a smart phone, a personal computer, and/or the like. In this example, current flow may be detected by the current transducer 106 of the one or more data collection units 102 and data based on the current flow may be output on another device, such as a smart phone, a personal computer, and/or the like.

As described herein, an incorrect CT hookup can be adjusted logically inside the device 700 itself, while still providing users with the flexibility to hook up their devices in whatever configuration they desire. In aspects, the device 700 may be configured and/or operable with a ‘Phase Correction’ feature that makes fixing an incorrect CT hookup a simple click of a button. In aspects, this can be done in the field using an application on a smart phone, a network connection via PC, and/or the like, which will be referred to as an application hereinafter for brevity.

When initializing an applicable implementation of the device 700, users can select a “Phase Correction” mode that that may allow users to implement modes, such as: Disabled (default), Automatic, Manual, and/or the like.

In aspects, the device 700 may be configured and/or operable to implement a disabled mode. In aspects, the disabled mode may be the default mode, and it may allow users to use the physical hookup as is. For example, if the channel 1 CT is hooked to channel 2, then that is what is measured for channel 1. The phase adjustment mapping for this mode is illustrated as output-interface 701 in FIG. 3.

In aspects, the device 700 may be configured and/or operable to implement an auto-fix mode. In aspects, the auto-fix mode may attempt to determine if the physical hookup is wrong, and may perform a logical swap or invert the polarity of channels as necessary. This auto-correction may be implemented at the end of a recording initialization countdown. During the countdown, the physical hookup may be used for measurements. This is how the device 700 may determine what needs to be adjusted, if anything. The output-interface 702 is a mapping that shows the adjustment for a device with channel 1 and channel 2 having CTs that were swapped, and a channel 3 CT that was inverted.

In aspects, the device 700 may be configured and/or operable to implement a manual mode. In the manual mode, the user may specify a logical arrangement of the channels and their inversion with reference to output-interface 703 illustrated in FIG. 5. In aspects, a user may drag channels from the left side (physical) to the desired channel on the right (logical). Selecting the “Invert” button will reverse the polarity for a physical channel. The user-defined mapping may be applied at the start of the recording initialization countdown.

In the following example, the user has accidentally hooked the channel 1 CT around the second phase, the channel 2 CT around the first phase, and the channel 3 CT around the third phase, but put the channel 3 CT on backwards. They have chosen to re-initialize their recording using the manual mode, with physical channel 1 mapped to logical channel 2, physical channel 2 mapped to logical channel 1, and inverted the polarity on channel 3. This will make their recorded data match their intended hookup of channel 1 to channel 1, channel 2 to channel 2, and channel 3 to channel 3.

One instance in which the manual map mode may be used is where a breaker is open during installation. If the auto-adjustment cannot sense current in a CT, then the correction algorithm cannot properly make recommendations. Once the breaker is closed, however, it may become apparent that the CTs have been improperly installed. It is at this time that the user has the ability to manually correct the installation from the application.

Note that the user can also select “auto-detect” again and re-initialize the recording. This may allow the device 700 to recommend corrective action (if necessary).

As described in the following sections, users can view what phase correction mapping is being used on the device 700 as well as toggle viewing certain recorded data as mapped and as the physical hookup.

In aspects, the device 700 may be configured and/or operable for initializing a phase correction routine. When initializing a recording in the application, the device 700 may be configured to allow a user to select a phase correction mode, as seen in output-interface 704 illustrated in FIG. 6 and/or output-interface 705 illustrated in FIG. 7.

In aspects, the device 700 may be configured and/or operable for viewing phase correction. In the application a user can view the phase correction mapping used for a recording, based on which phase correction mode the user has selected. The mapping may be viewed by selecting the “View” button next to “Phase Correction” in the recording's header report.

In aspects, the device 700 may be configured and/or operable for generating a view that after downloading a recording, a user can view the phase correction mapping used for that recording, based on which phase correction mode a user selected. In aspects, the mapping can be viewed by selecting the “Phase Correction” in the recording's header report as illustrated in output-interface 706 in FIG. 8, output-interface 707 in FIG. 9, output-interface 708 in FIG. 10, and output-interface 709 in FIG. 11.

In aspects, the device 700 may be configured and/or operable for toggling phase correction. In aspects, when viewing live data for a recorder-waveforms, vector diagrams, meter data, and/or the like, the application and/or the device 700 may be configured and/or operable to allow selection of a toggle button, which will display the same data using the physical hookup instead of the configured phase correction mapping as illustrated in, outputs-interfaces 710 in FIG. 12.

In aspects, the device 700 may be configured and/or operable for hookup validation. In aspects, the application may be configured and/or operable to auto-detect issues with a hookup of the device 700. In aspects, the device 700 may be configured and/or operable to analyze live waveform data to determine if any CTs are hooked up wrong.

If any issues are detected, a notification may be generated as illustrated by output-interface 711 in FIG. 13. When clicked, the notification may display a suggestion on how to correct the hookup as illustrated in output-interface 712 in FIG. 14. This may be performed physically or by re-initializing with a manual phase correction map configured in the suggested way. In aspects, the device 700 may be configured and/or operable to allow a user to re-initialize with the automatic phase correction mode.

In aspects, the device 700 may be configured and/or operable to Disable Warnings as illustrated in output-interface 713 and FIG. 15.

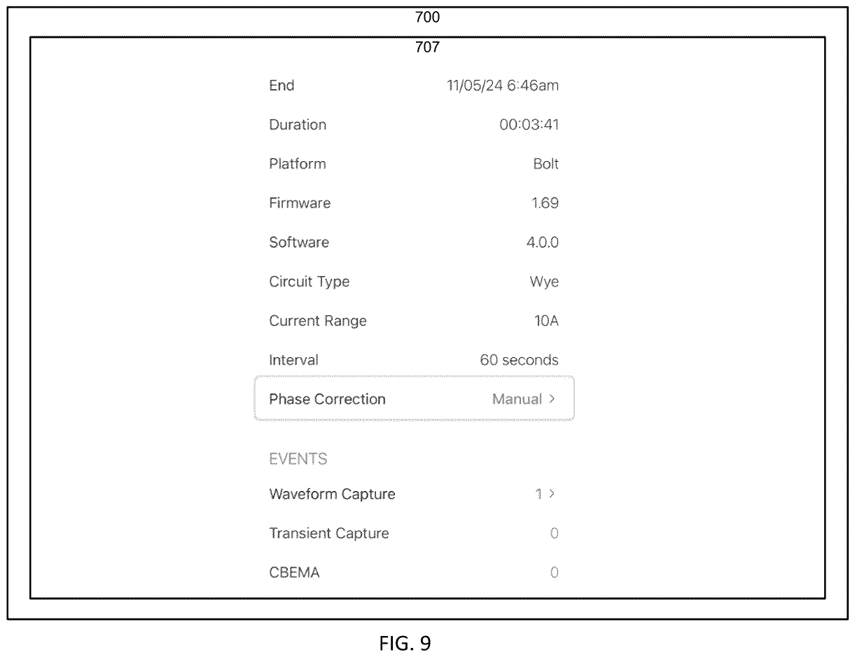

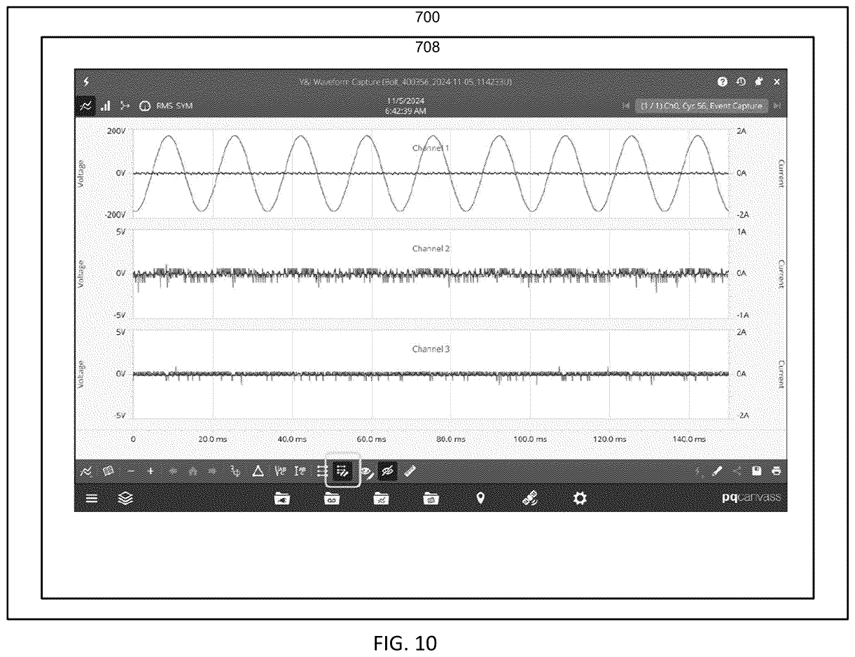

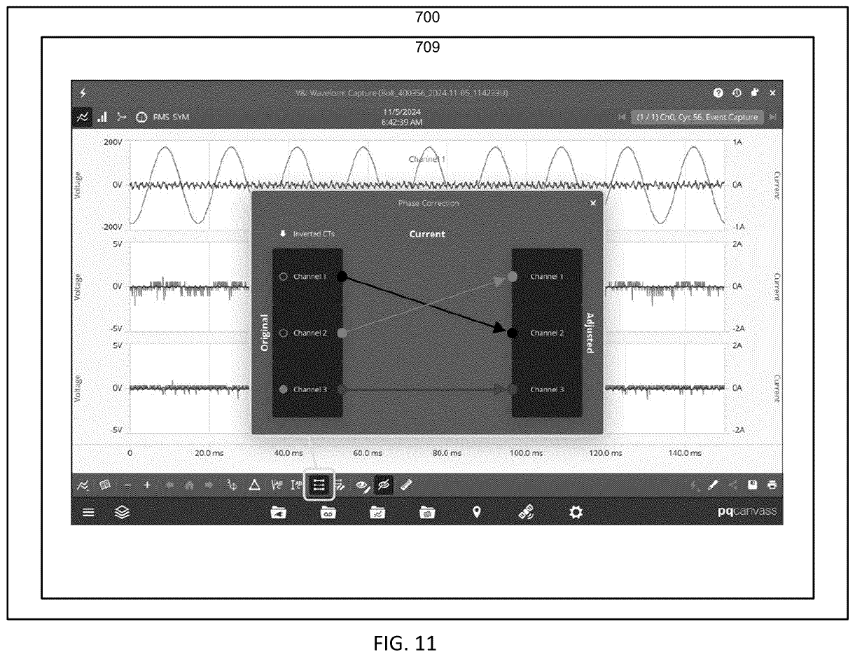

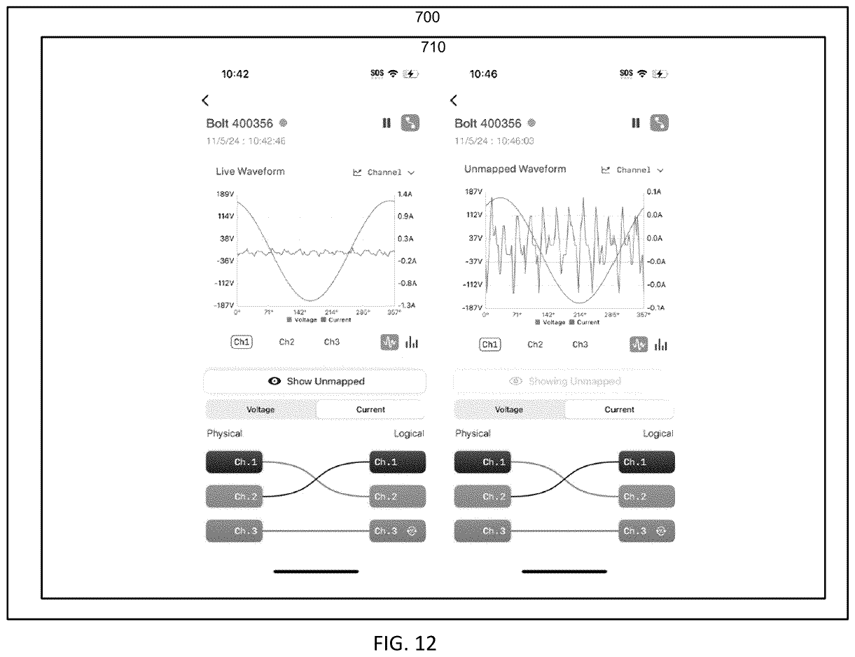

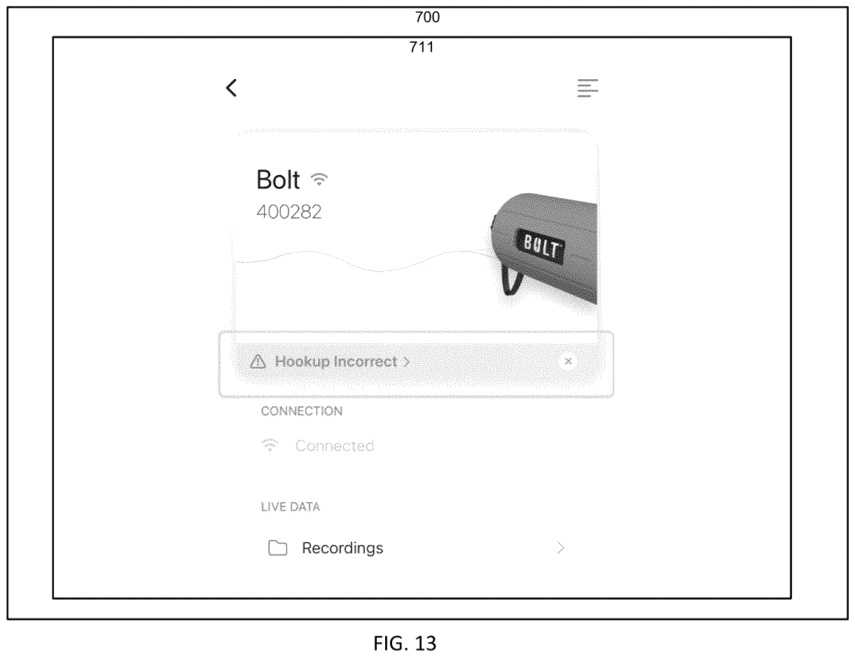

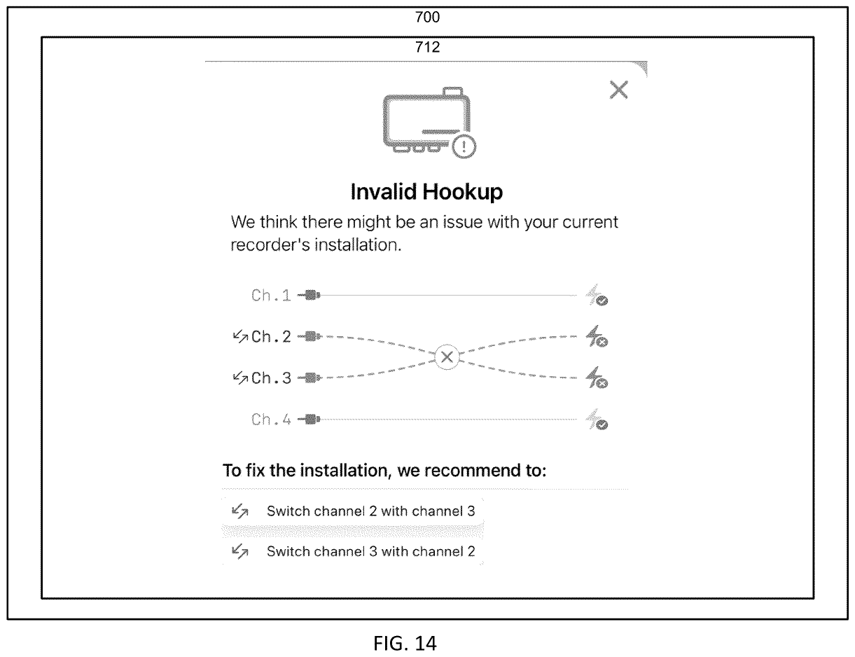

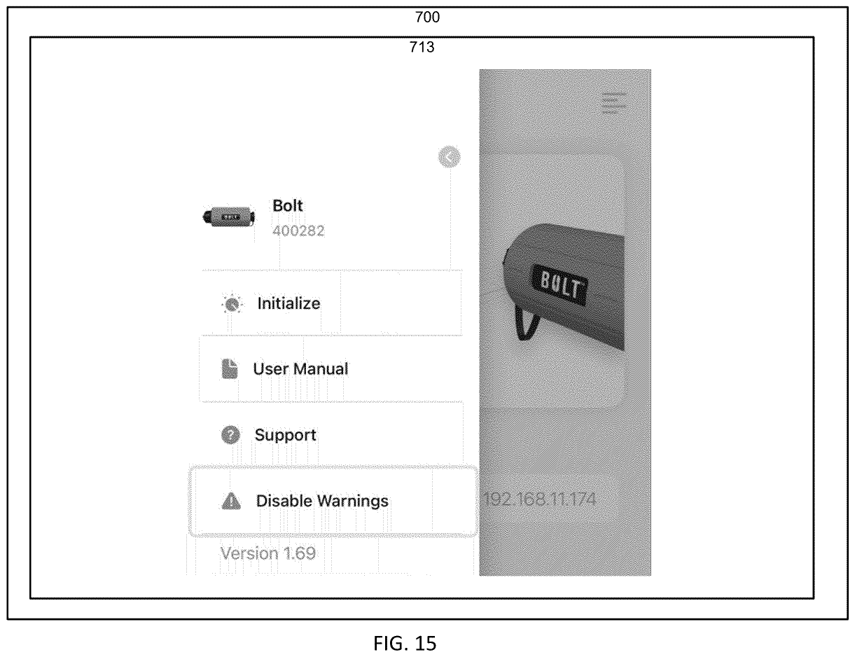

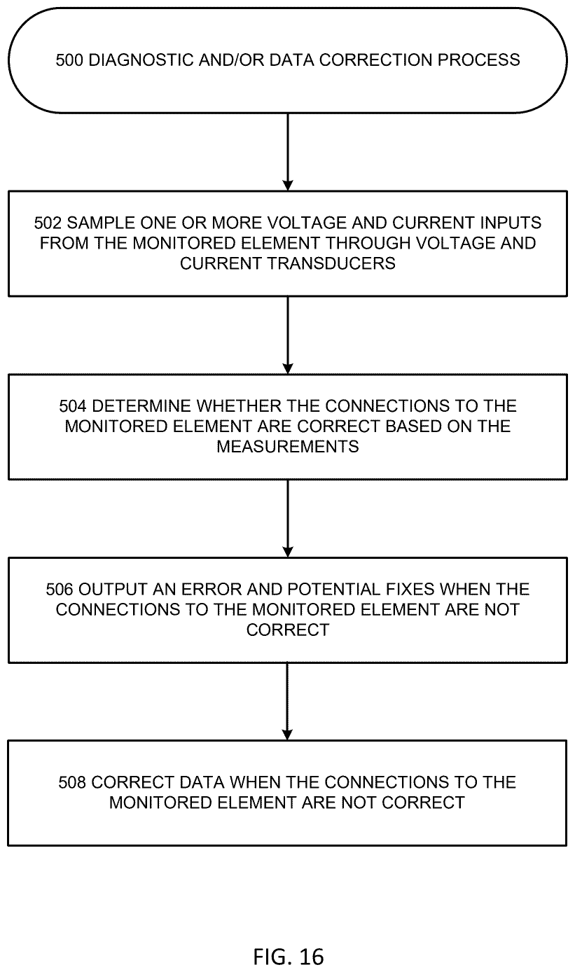

FIG. 16 shows an exemplary diagnostic and/or data correction process according to aspects of the disclosure.

In particular, FIG. 16 shows an exemplary diagnostic and/or data correction process 500. In particular, it should be noted that the diagnostic and/or data correction process 500 is merely exemplary and may be modified consistent with the various aspects disclosed herein. Moreover, the diagnostic and/or data correction process 500 may include a process of implementing the electric power data collection and analysis system 100, the one or more data collection units 102, the data concentrator 150, the cloud-based analytics system 300, another system, another device, and/or the like. It should be noted that the diagnostic and/or data correction process 500 may be performed in a different order consistent with the aspects described above. Moreover, the diagnostic and/or data correction process 500 may be modified to have more or fewer process steps consistent with the various aspects disclosed herein.

The diagnostic and/or data correction process 500 may include sample one or more voltage and current inputs from the monitored element through voltage and current transducers 502. In this regard, the sample one or more voltage and current inputs from the monitored element through voltage and current transducers 502 may include any one or more materials, structures, arrangements, processes, and/or the like as described herein. Moreover, one or more proceeding or subsequent processes may also be implemented with respect to the sample one or more voltage and current inputs from the monitored element through voltage and current transducers 502 consistent with the disclosure.

In aspects the sample one or more voltage and current inputs from the monitored element through voltage and current transducers 502 may include sampling one or more voltage and current inputs by the electric power data collection and analysis system 100, the one or more data collection units 102, the data concentrator 150, the cloud-based analytics system 300, another system, another device, and/or the like as described herein.

The diagnostic and/or data correction process 500 may include determine whether the connections to a monitored element are correct based on the measurements 504. In this regard, the determine whether the connections to a monitored element are correct based on the measurements 504 may include any one or more materials, structures, arrangements, processes, and/or the like as described herein. Moreover, one or more proceeding or subsequent processes may also be implemented with respect to the determine whether the connections to a monitored element are correct based on the measurements 504 consistent with the disclosure.

In aspects the determine whether the connections to a monitored element are correct based on the measurements 504 may include determining the connections to a monitored element are correct based on the measurements by the electric power data collection and analysis system 100, the one or more data collection units 102, the data concentrator 150, the cloud-based analytics system 300, another system, another device, and/or the like as described herein.

The diagnostic and/or data correction process 500 may include output an error and potential fixes when the connections to the monitored element are not correct 506. In this regard, the output an error and potential fixes when the connections to the monitored element are not correct 506 may include any one or more materials, structures, arrangements, processes, and/or the like as described herein. Moreover, one or more proceeding or subsequent processes may also be implemented with respect to the output an error and potential fixes when the connections to the monitored element are not correct 506 consistent with the disclosure.

In aspects the output an error and potential fixes when the connections to the monitored element are not correct 506 may include outputting errors and potential fixes by the electric power data collection and analysis system 100, the one or more data collection units 102, the data concentrator 150, the cloud-based analytics system 300, another system, another device, and/or the like as described herein.

The diagnostic and/or data correction process 500 may include correct data when the connections to the monitored element are not correct 508. In this regard, the correct data when the connections to the monitored element are not correct 508 may include any one or more materials, structures, arrangements, processes, and/or the like as described herein. Moreover, one or more proceeding or subsequent processes may also be implemented with respect to the correct data when the connections to the monitored element are not correct 508 consistent with the disclosure.

In aspects the correct data when the connections to the monitored element are not correct 508 may include correcting the data by the electric power data collection and analysis system 100, the one or more data collection units 102, the data concentrator 150, the cloud-based analytics system 300, another system, another device, and/or the like as described herein.

The aspects of the diagnostic and/or data correction process 500 illustrated in FIG. 16 and described therewith, may optionally be implemented in any other aspects of the electric power data collection and analysis system 100, the one or more data collection units 102, the data concentrator 150, the cloud-based analytics system 300, another system, another device, and/or the like illustrated in the other figures and described therewith. Further, the aspects of the electric power data collection and analysis system 100, the one or more data collection units 102, the data concentrator 150, the cloud-based analytics system 300, another system, another device, and/or the like illustrated in the other figures and described therewith may optionally be implemented in the aspects of the diagnostic and/or data correction process 500 illustrated in FIG. 16.

As previously noted, implementation of the diagnostic and/or data correction process 500 may be by the electric power data collection and analysis system 100, the one or more data collection units 102, the data concentrator 150, the cloud-based analytics system 300, another system, another device, and/or the like. In aspects, the electric power data collection and analysis system 100, the one or more data collection units 102, the data concentrator 150, the cloud-based analytics system 300, another system, another device, and/or the like may or may not include additional features as described herein. In aspects, the electric power data collection and analysis system 100, the one or more data collection units 102, the data concentrator 150, the cloud-based analytics system 300, another system, another device, and/or the like may or may not implement the process for electric power data collection and analysis 600 as described herein.

With reference to FIG. 2, the voltage transducer 104 may be configured to measure an electrical parameter such a voltage associated with the monitored element 400. In this regard, the voltage transducer 104 may be configured with components, circuits, and/or the like for voltage measurement.

In aspects, the current transducer 106 may be configured to measure an electrical parameter such as a current associated with the monitored element 400. In this regard, the current transducer 106 may be configured with components, circuits, and/or the like for current measurement.

In aspects, the one or more data collection units 102 may include multiple implementations of the voltage transducer 104. In aspects, the one or more data collection units 102 may include multiple implementations of the current transducer 106. In aspects, the one or more data collection units 102 may include multiple implementations of the voltage transducer 104 and multiple implementations of the current transducer 106. In aspects, the one or more data collection units 102 may include one or more implementations of the voltage transducer 104 without any implementations of the current transducer 106. In aspects, the one or more data collection units 102 may include one or more implementations of the current transducer 106 without any implementations of the voltage transducer 104.

In aspects, the one or more data collection units 102 may include a processor 110, such as a DSP (digital signal processor). The processor 110 may be configured for data collection, pre-processing, analytic operations, and/or the like. The one or more data collection units 102 may include a second processor 112. The second processor 112 may be configured for data buffering, communication, and/or the like.

FIG. 17 illustrates a data concentrator according to aspects of the disclosure.

The data concentrator 150 may be configured to receive periodic data blocks and/or the like from the one or more data collection units 102. The data concentrator 150 may be configured to receive raw waveform data and/or other data from the one or more data collection units 102. Additionally, the data concentrator 150 may be configured to provide timestamps, compress the data in a format suitable for storage, store the data in an organized fashion for later retrieval, and/or the like.

With reference to FIG. 17, if the data concentrator 150 is not connected to the network 200, the data concentrator 150 may be configured to continue to accumulate the data locally in compressed format, periodically transfer the data to a storage device 152, such as a removable storage device. In one or more aspects, the storage device 152 may be implemented as a removable Universal Serial Bus (USB) Flash drive. In this regard, the storage device 152 implemented as a removable Universal Serial Bus (USB) Flash drive may be implemented as a data storage device that includes flash memory with an integrated USB interface.

In this regard, the data concentrator 150 may be configured to allow a user to periodically physically swap the storage device 152. For example, the user may once a week, once a month, and/or the like physically swap the storage device 152. In this regard, the data concentrator 150 may be configured to store continuous waveform data from the monitored element 400 in compressed format. Accordingly, the storage device 152 removed from the data concentrator 150 may have the continuous waveform data from the monitored element 400 stored in the compressed format.

Additionally, the user may provide a replacement implementation of the storage device 152 to the data concentrator 150. In this regard, the replacement implementation of the storage device 152 may be a previously utilized implementation of the storage device 152 that has been previously utilized and the data stored thereon erased. Thereafter, the replacement implementation of the storage device 152 may be utilized by the data concentrator 150 for further data accumulation. For example, the replacement implementation of the storage device 152 may be utilized to store subsequent continuous waveform data from the monitored element 400 stored in the compressed format.

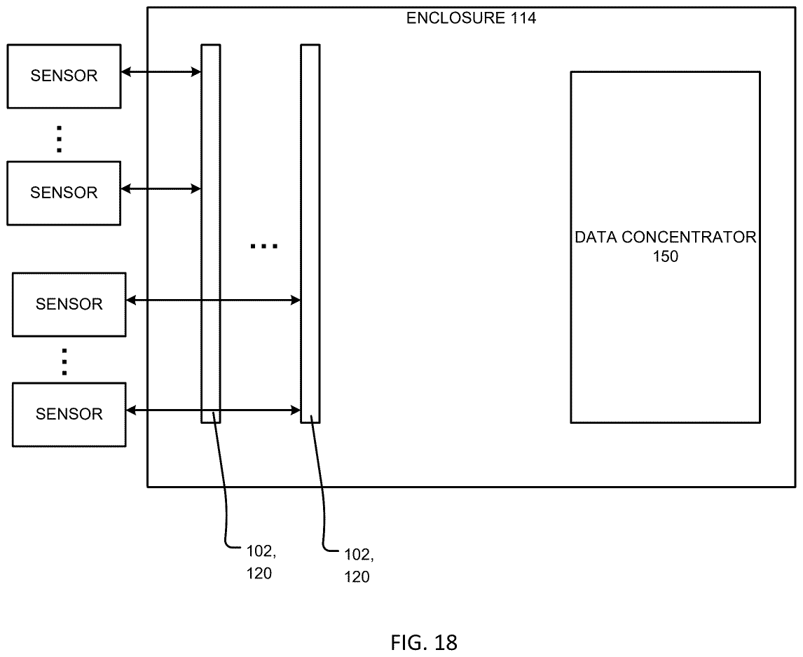

FIG. 18 illustrates further aspects of a data collection unit according to aspects of the disclosure.

In aspects, the one or more data collection units 102 may be arranged in an enclosure 114. In aspects, the enclosure 114 may be a rack enclosure for the one or more data collection units 102. In aspects, the enclosure 114 may include one or more fastening systems, structural support systems, rails, cooling systems, and/or the like. In aspects, the enclosure 114 may hold card implementations 120 of the one or more data collection units 102.

For example, the enclosure 114 may be a standard 19″ rack enclosure. In aspects, the enclosure 114 may be configured as a 2U enclosure containing a plurality of the card implementations 120 of the one or more data collection units 102. In aspects, the enclosure 114 may hold a plurality of the card implementations 120 of the one or more data collection units 102 implemented as 3-phase data collection units (“cards”). In aspects, the enclosure 114 may hold 12 individual configuration of the card implementations 120 of the one or more data collection units 102 implemented as 3-phase data collection units (“cards”).

Each of the card implementations 120 of the one or more data collection units 102 may have connectorized inputs for a plurality of voltage signals, a CT (Current Transformer) connector for a plurality of current inputs, and/or the like. For example, each of the card implementations 120 of the one or more data collection units 102 may have connectorized inputs for 3 or 4 voltage signals, and a CT connector for 3 or 4 current inputs.

For example, a typical voltage input level may be 120 V RMS, from monitoring PTs (Potential Transformers) outside the electric power data collection and analysis system 100. In aspects, the electric power data collection and analysis system 100 and/or the card implementations 120 of the one or more data collection units 102 may accept inputs up to 300 V RMS or 600 V RMS.

In aspects, the electric power data collection and analysis system 100 and/or the card implementations 120 of the one or more data collection units 102 may be configured for current inputs that typically monitor 5 amps (A) metering CT secondaries. In aspects, the electric power data collection and analysis system 100 and/or the card implementations 120 of the one or more data collection units 102 may allow for various current ranges and CT assemblies, for use with 5 A metering CTs and also for cases where a main current (hundreds or thousands of amps) may be measured.

In aspects, the card implementations 120 of the one or more data collection units 102 may be a dual-processor system that may implement the processor 110 and the second processor 112. In aspects, the processor 110 may be implemented as a primary ARM (Advanced RISC Machine) processor. In aspects, the processor 110 may be implemented as a primary ARM processor running embedded Linux.

In aspects, the second processor 112 may be implemented as a secondary DSP processor. In aspects, the second processor 112 may be implemented as a secondary DSP processor handling data sampling, pre-processing, and/or the like.

The card implementations 120 of the one or more data collection units 102 may also include a high-speed A/D converter that may be implemented as part of the sampling system 108 and signal conditioning circuitry 116.

The card implementations 120 of the one or more data collection units 102 may be configured for data sampling. In aspects, the card implementations 120 of the one or more data collection units 102 may be configured for data sampling at 256 samples per 60 Hz cycle (15,360 Hz) per signal. Other sampling rates, such as lower sampling rates (as low as 64 samples per cycle) are possible in some configurations of the one or more data collection units 102. A higher sampling rate (such as 1 MHz) may be used to allow characterization of high frequency powerline noise signals, fast risetime transients, other high frequency signals that may be useful in machine learning training, and/or the like.

The A/D that may be implemented as part of the sampling system 108 may have any desired resolution. In aspects, the A/D that may be implemented as part of the sampling system 108 may have a resolution of at least 14 or 16 bits.

In aspects, the A/D that may be implemented as part of the sampling system 108 may implement oversampling techniques. The oversampling techniques may be used to trade off resolution and sampling rate. In one aspect, sampling by the A/D may be performed at 250 kHz with a 14 bit resolution, and the DSP implementation of the second processor 112 may downsample to 15,360 Hz with increased resolution. The downsampling performed by the DSP implementation of the second processor 112 may also incorporate phase locking so that the downsampled waveform may be synchronous to a 60 Hz reference signal (e.g. voltage channel one), even if the high speed raw data at 250 kHz is not synchronous. This may be accomplished by the DSP implementation of the second processor 112 utilizing continuous fast Fourier transform (FFT) analysis of the reference signal, and tracking the 60 Hz phase information, then adjusting the downsampled rate accordingly.

The one or more data collection units 102 may be configured such that voltage inputs and current inputs may be sampled simultaneously. Alternatively, the one or more data collection units 102 may be configured such that voltage inputs and current inputs may be sampled serially with signal pre-processing applied later if needed to re-align the signals.

Each of the card implementations 120 of the one or more data collection units 102 may individually phase lock to its channel one voltage signal (or another reference channel on the card). In aspects, the card implementations 120 of the one or more data collection units 102 may synchronize sampling to a primary card via digital sync connection, to an external timebase via a global navigation satellite system (GNSS), such as the Global Positioning System (GPS), which may implement one pulse per second input, IRIG-B input (Inter-range instrumentation group timecodes), IEEE-1588 timing, and/or the like. In aspects, the electric power data collection and analysis system 100 and/or a component of the electric power data collection and analysis system 100 may include a device to receive signals from a GNSS, such as GPS.

In aspects, the voltage inputs on the card implementations 120 of the one or more data collection units 102 may have a single common voltage reference. In aspects, each of the card implementations 120 of the one or more data collection units 102 may have has its own reference input. In aspects, the card implementations 120 of the one or more data collection units 102 may be configured for voltage inputs that may be fully differential.

The second processor 112 may be configured to collect continuous waveform data from the inputs. Additionally, the second processor 112 may apply pre-processing. The preprocessing implemented by the second processor 112 may include scaling, timing adjustments, downsampling, and/or the like. Further, the second processor 112 may buffer data in a memory 122.

The second processor 112 may be configured to transfer data to other components within the card implementations 120 of the one or more data collection units 102. For example, the second processor 112 may be configured to transfer data to the processor 110. In particular, the second processor 112 may periodically transfer a batch of continuous data to the processor 110. In this regard, periodically can be for example an n number of 60 Hz cycles, such as every one or two 60 Hz cycles. In one aspect, the second processor 112 may be configured to transfer data to the processor 110 over a bus 124, which may be a local bus, a local Serial Peripheral Interface (SPI) bus, and/or the like.

The processor 110, which may be running embedded Linux, receives this buffer or transfer data from the second processor 112 and the processor 110 adds the transfer data to its accumulation data in the memory 122 or another memory. After accumulating sufficient data (typically 10 seconds worth), the processor 110 may transfer this data to the data concentrator 150 via a connection between the data concentrator 150 and the one or more data collection units 102. The connection between the data concentrator 150 and the one or more data collection units 102 may be implemented by a local Ethernet connection and/or the like.

Although the primary purpose of the card implementations 120 of the one or more data collection units 102 is to capture and send data, such as continuous voltage waveform data, current waveform data, and/or the like to the data concentrator 150, the one or more data collection units 102 may be configured for other tasks. In some aspects, the second processor 112 and the processor 110 together may provide full power quality monitoring, triggering, and/or the like including standard PQ (Power Quality) metrics such as IEEE 1453 flicker, harmonic measurements as per IEEE 519, and/or the like. In addition, the second processor 112 may also compute other derivative signals that may be useful, such as phasor measurement unit (PMU) data, that may be accumulated in the same manner as the raw voltage and current waveforms.

The electric power data collection and analysis system 100, the processor 110, and/or the second processor 112 may also be configured as an engine to execute AI/ML algorithms, data filtering, and/or the like. Additionally, these and other processes may be downloaded with future updates. These algorithms may be configured and used for predictive analytics to indicate impending powerline or equipment failures, detect system stability issues, flag equipment problems (e.g. capacitor banks not switching correctly, blown fuses, etc.) help identify the location of problems, and/or the like. Additionally, these algorithms may also be configured and used to filter out harmless disturbances such as mains signaling, timing pulses, and/or the like.

The processor 110 on the collection card may be connected to the data concentrator 150 via wired or wireless connection such as an Ethernet connection. An internal subnet inside the electric power data collection and analysis system 100 may connect all data cards to the data concentrator 150. In an aspect, each collection card has a unique slot number and internal IP address. After collecting data from the second processor 112 over a suitable time period (e.g. 10 seconds), the data may be sent from the processor 110 to the data concentrator 150 via standard User Datagram Protocol (UDP) link, a Transmission Control Protocol (TCP) link, and/or the like. The processor 110 may handle other housekeeping tasks such as maintaining card calibration and configuration information, detecting the connection and removal of current clamps, and/or the like. In one aspect, the processor 110 may also record and store standard power quality information in a local memory storage, such as the memory 122. In other aspects, one or more of the features, functionality, and/or the like of the processor 110 may be implemented by the second processor 112; and/or one or more of the features, functionality, and/or the like of the second processor 112 may be implemented by the processor 110.

In other aspects, the features, functionality, and/or the like of the processor 110 and the second processor 112 may be combined and implemented in a single processor or additional processors. In one aspect, the features, functionality, and/or the like of the processor 110 and the second processor 112 may be combined and implemented in a processor 130 as illustrated by dashing in FIG. 2.

In an aspect, the data concentrator 150 may be implemented as and/or may include an x86 Single Board Computer (SBC), hereinafter an SBC 156. For example, the SBC 156 may be implemented as an Odyssey X86J4105864 running Linux.

The SBC 156 may have a plurality of Ethernet ports, for example the SBC 156 may have two Ethernet ports, one dedicated to the Ethernet switch 176, such as an internal 16 port Ethernet switch that also connects to the collection cards; and one brought to the front panel for debugging and local user connection. The SBC 156 may have 2 TB or more of local Flash storage 158 to collect data if no external storage is available. The SBC 156 may have a USB port 160, such as a USB 3.0 port, that may be exposed at a front panel for a user to insert a high capacity USB Flash drive (typically 1 TB or more), such as the storage device 152. In normal operation, data may be received by the storage device 152 from the card implementations 120 of the one or more data collection units 102 periodically, for example every 10 seconds. The data may be formatted and stored in accumulating files on the local Flash storage 158. If a USB Flash drive is present, such as the storage device 152, this data may be periodically, for example once an hour, copied to that Flash drive, and erased from the local storage. If the USB Flash drive is full, or missing, data may continue to be accumulated on local storage, such as a memory 154, the local Flash storage 158, and/or the like until an empty Flash drive appears.

In one aspect, the SBC 156 may have a second Ethernet port 162 that may be exposed at the front panel of the data concentrator 150. If the second Ethernet port 162 is connected to local area network (LAN), such as a high speed LAN, waveform data may be transferred directly from the SBC 156 to the cloud-based analytics system 300, in addition to or in lieu of storage on the memory 154, the local Flash storage 158, and/or the like. The second Ethernet port 162 may also be used for IEEE 1588 time synchronization, remote device management, other cloud-based data analytics connections, and/or the like.

The SBC 156 may implement a real time clock (RTC) 164 that may be configured to keep local time, preferably with a battery backup. The second Ethernet port 162 may also be used for connection to a time server for synchronization.

In one aspect, the SBC 156 may include a Wi-Fi (wireless fidelity)/BLE (Bluetooth Low Energy) module 166 that allows for connection to a local LAN via Wi-Fi, and local wireless management of the device through BLE using a smartphone application, a tablet application, and/or the like. The SBC 156 may be configured to allow spot checks of waveform data, configuration, other management tasks, and/or the like, which may be completed through the BLE link.

In one aspect, the SBC 156 may include a modem 168, such as an embedded LTE modem. The modem 168 may be implemented as the Quectel EM06-A, a CAT 6 high speed modem, and/or the like. In some areas, this LTE connection may be fast enough to stream some or all continuous waveform data from the data concentrator 150 to the cloud-based analytics system 300. The modem 168 may also be used in the same manner as the second Ethernet port 162, for remote device management of the electric power data collection and analysis system 100, the one or more data collection units 102, the data concentrator 150, and/or the like.

The SBC 156 may include output devices 170. The output devices 170 may include LED status lights from the SBC 156 on the front panel to indicate device status, readiness of the USB external drive, and/or the like. In some aspects, the output devices 170 may be implemented as a front panel LCD display that may be used for presenting more information. The SBC 156 may include High-Definition Multimedia Interface (HDMI) port 172, which may also be exposed at the front panel in some embodiments. In other aspects, the features, functionality, and/or the like of the SBC 156 may be implemented in additional processors, additional computers, and/or the like.

In one aspect, the data concentrator 150 may include an internal power supply 174. The internal power supply 174 may take 120 VAC power and provide isolated low voltage supplies, for example 12 VDC and 5 VDC, for the SBC 156, the card implementations 120 of the one or more data collection units 102, the Ethernet switch 176, a cooling fan, and/or the like. In one aspect, the data concentrator 150 may include a rack-mounted 120 V uninterruptible power source (UPS) configured to provide backup power if needed.

In one aspect, the electric power data collection and analysis system 100, the one or more data collection units 102, the data concentrator 150 and/or the like may be adjacent the monitored element 400. The monitored element 400 may be an electrical substation, a solar farm, a wind farm, a Distributed Energy Resource (DER), a portion of a utility transmission infrastructure, a portion of a utility generation infrastructure, one or more circuits, one or more machines, one or more components, and/or the like.

The electric power data collection and analysis system 100, the one or more data collection units 102, the data concentrator 150, and/or the like may be configured as an installation. The installation may include the enclosure 114. In aspects, the installation may include mounting one or more components of the electric power data collection and analysis system 100, the one or more data collection units 102, the data concentrator 150, and/or the like in a rack, such as a standard 19 inch rack. Additionally, the installation may include the voltage input connections and current input connections to the monitored element 400 to be monitored, and applying 120 V power. A blank configuration of the memory 154, such as 1 TB USB drive, may be inserted in the front panel of the data concentrator 150, and upon power up, the electric power data collection and analysis system 100, the one or more data collection units 102, the data concentrator 150, and/or the like will begin collecting data from the monitored element 400. With a typical 12 circuit configuration the memory 154 may be full in 1-2 weeks. If there is no wired or wireless connection, such as a LAN connection, a user will come to the electric power data collection and analysis system 100 to swap USB drives. The electric power data collection and analysis system 100 may implement larger drives to reduce the number of on-site visits.

If a low-speed wired or wireless connection is available, for example a low data rate cell, a limited LAN connectivity via Ethernet, and/or the like, a subset of recorded data by the electric power data collection and analysis system 100 may be streamed off-site, in parallel with the local drive recording mechanism.

In one or more aspects, the data concentrator 150 may present a web interface on any exposed network port, a cell connection, the second Ethernet port 162, via Wi-Fi, and/or the like.

In some embodiments or use cases, the electric power data collection and analysis system 100 may be configured to provide a differing number of voltage and current channels. For example, in situations with multiple circuits that share a common voltage bus, a single three phase voltage input may suffice for all circuits, but each circuit has its own three phase current signals. The electric power data collection and analysis system 100 may be configurable to enable or disable voltage and current channels as needed to avoid storing redundant data. If only one voltage circuit is needed, individual implementations of the card implementations 120 of the one or more data collection units 102 may all synchronize to that common voltage input, without need to record redundant voltage inputs. Alternatively, the data the card implementations 120 of the one or more data collection units 102 may synchronize to their own current inputs, to an external timing pulse (e.g. from GPS, IRIG-B, or IEEE 1588 as described above), and/or the like.

For large systems, multiple implementations of the electric power data collection and analysis system 100 may be placed in the same rack. The second Ethernet port 162 may be used to connect the multiple implementations of the electric power data collection and analysis system 100 together to form a small network—e.g. to share a common LAN connection, share timing synchronization, or share a common large storage pool.

In one aspect, the SBC 156, the data concentrator 150, the card implementations 120 of the one or more data collection units 102 may all be contained in a single 19 inch rack enclosure, interconnected via internal Ethernet connections with a multi-port switch. In other embodiments the components may be distributed. For example, data the card implementations 120 of the one or more data collection units 102 may be standalone units with integral power supply, or the data concentrator 150 may be a separate rack mounted server or other networked device. A hybrid implementation is also possible, with an SBC in the standard rack configuration with the card implementations 120 of the one or more data collection units 102 also receiving data from external devices via the second Ethernet port 162. In some implementations, a PQ monitor such as the Power Monitor, Inc. (PMI) Seeker, Revolution, Tensor, or other networked device may act as a data collection card, feeding data to the data concentrator 150. In this configuration, the Seeker or other device may incorporate its own GPS timing synchronization, or utilize timing signals via wireless or wired connection from the data concentrator 150, or other available timing reference. Another possible embodiment is a virtual concentrator implementation of the data concentrator 150, with data collection devices streaming data through a network, a cellular data connection, a communication channel as defined herein, and/or the like to the cloud-based analytics system 300, a cloud-based receiver, and/or the like. This virtual concentrator implementation of the data concentrator 150 may be a virtual machine on a hosted system, a scalable system, such as Amazon Web Services (AWS), and/or the like.

The basic data collection system may include the card implementations 120 of the one or more data collection units 102 and the data concentrator 150, gathering raw bulk waveform data needed for ML/AI training. In a more advanced embodiment, the waveform data may be periodically fed into the ML/AI system, the cloud-based analytics system 300, and/or the like, which may use this data, possibly in combination with outside information, data, measurements, and/or the like such as known system device operation (e.g. reclosers, circuit breakers, and/or the like), equipment failures, and/or the like. In aspects, the electric power data collection and analysis system 100 and/or a component of the electric power data collection and analysis system 100 may collect the outside information, data, measurements, and/or the like consistent with the collection of the waveform data.

The waveform data and the outside information, data, measurements, and/or the like may be utilized to train the ML/AI system, the cloud-based analytics system 300, and/or the like to create waveform signatures, train one or more neural networks, generate one or more algorithms, and/or the like that may be utilized to predict future events. These waveform signatures, one or more neural networks, one or more algorithms, and/or the like may be loaded onto a device, the electric power data collection and analysis system 100, the cloud-based analytics system 300, and/or the like either manually, or automatically. The device, the electric power data collection and analysis system 100, the cloud-based analytics system 300, and/or the like may implement these waveform signatures, one or more neural networks, one or more algorithms, and/or the like to create alerts when these patterns are detected. In aspects, the waveform signatures, one or more neural networks, one or more algorithms may be generated, trained, implemented, and/or the like utilizing artificial intelligence and/or machine learning as defined herein. The alerts may be transferred to the SBC 156 and upstream to the cloud-based analytics system 300, a cloud-based, and/or other system to send email notifications, SMS notifications, Supervisory Control And Data Acquisition (SCADA) notifications, and/or other notifications as needed.

The electric power data collection and analysis system 100 and/or the cloud-based analytics system 300 may also be connected to a SCADA system via Distributed Network Protocol 3 (DNP3), MODBUS, IEC 61850, and/or other protocol. It can operate as a SCADA remote terminal unit (RTU), making data collection card data available to a SCADA master, and sending unsolicited reports by exception. In most cases, raw waveform data would not be suitable for SCADA transfer, rather the SBC 156 would send aggregate measures from the card implementations 120 of the one or more data collection units 102 such as RMS voltage, current, real power, harmonic distortion, and/or the like. In some embodiments, the card implementations 120 of the one or more data collection units 102 or the SBC 156 may have relay or digital inputs and outputs controllable by the SCADA system, to facilitate SCADA switching or operation of external devices such as relays, contactors, breakers, and/or the like, in parallel with the devices primary function as a data collection system.

In some embodiments, a networked device may send periodic data to a cloud based system such as PMI's PQ Canvass system. Some or all of the collected data may be presented to the user via the web interface of the cloud system, either as raw waveforms, or as computed PQ information.

In one or more aspects, the electric power data collection and analysis system 100, the one or more data collection units 102, the data concentrator 150, and/or the like may include communication ports for interfacing with external sensors. The communication ports may be implemented utilizing any known technology including RS-485, Ethernet, RS-232, wireless links, and/or the like. In one aspect, the external ports may include a SCADA port.

In one or more aspects, the electric power data collection and analysis system 100, the one or more data collection units 102, the data concentrator 150, and/or the like may include embedded technology to control cell modems, satellite modems, process data from external ports, interface the monitored element 400, interface the cloud-based analytics system 300, perform real-time voltage, current, and power calculations, and/or the like the like.

FIG. 19 illustrates an exemplary implementation of a cloud-based server system according to aspects of the disclosure.

In particular, FIG. 19 illustrates an exemplary implementation of the cloud-based analytics system 300 that may be implemented as a cloud-based server system, and may be a collection of virtual machines and processes. The cloud-based analytics system 300 may be configured perform several functions: receive and parse data from one or more implementations of the electric power data collection and analysis system 100 as it streams in to the cloud-based analytics system 300; store all measured values as sent from the electric power data collection and analysis system 100; process any alerts from the electric power data collection and analysis system 100, including sending immediate message notices, such as email notices, text message notices, application based notices, and/or the like, to any triggered distribution list; provides a map-based graphical display of all the electric power data collection and analysis system 100 associated with a specific account; provide graphical and report-based data analysis tools for the user to view and analyze data; provide a control interface to send commands or query status of the electric power data collection and analysis system 100, or any other compatible device connected to the electric power data collection and analysis system 100 and/or the cloud-based analytics system 300; and/or provide a SCADA system interface to allow an external SCADA master to query information and send commands to the electric power data collection and analysis system 100.

The cloud-based analytics system 300 may further include one or more the following components, a data server 450, a concentrator listener 402, a data parser 404, an alarm service 406, an email/SMS service 408, a database 410, a data combiner 412, a data decimator 414, a file-based data storage 416, a scheduled report service 418, a Web server 420, a data set processor 422, a SCADA interface 424, and/or the like.

The user interaction with the cloud-based analytics system 300 may be through a standard web browser. The cloud-based analytics system 300 may utilize any other similar on-demand cloud computing platforms. An aspect may include a collection of Berkeley Software Distribution (BSD) or Linux-based virtual machine servers, including a server for receiving and parsing incoming packets the electric power data collection and analysis system 100, storing received measurements, processing and sending alert emails and SMS messages, storing device information, user information, account information, billing information, and/or the like in a SQL database, and providing web hosting (e.g. with Apache) for the user web application. In aspects the servers are connected in a private network, with only the web host including a separate, public network interface (to allow web browser connections). The electric power data collection and analysis system 100 may be networked inside a cell carrier private network, with a VPN connection to the data server 450.

The data server 450 may decompress data received from the electric power data collection and analysis system 100 and may store the measurement data. Although the data may be stored in a relational database, an aspect uses a binary file format to store individual packets. A separate combiner process may run in the background, reading the small stored packets and combining them into larger chunks (e.g. into a 24 hour chunk).

A web application hosted by the cloud-based analytics system 300 may present a map-based display of all implementations of the electric power data collection and analysis system 100 in a user's account. The electric power data collection and analysis system 100 may be located at the monitored element 400 manually by the user, or automatically located by using a global navigation satellite system (GNSS) such as GPS, or other positioning information sent by the electric power data collection and analysis system 100. A related heat map may be created from the analyzed data by the cloud-based analytics system 300, the electric power data collection and analysis system 100, and/or the like to show detected or predicted problem areas graphically overload on a geographic map of the area. Utility-supplied GIS (Graphical Information system) data with the location of utility assets and historical problem locations may be overlaid or combined with the analyzed data on a heat map.

The web page may be used to request the generation of reports in various formats (HTML, CSV, PDF, etc.) These reports may be raw measurements from one or more implementations of the electric power data collection and analysis system 100, alert history, account billing information, etc. The reports may be rendered immediately and presented to the user in the browser, or configured to be emailed on a scheduled basis.

The cloud-based analytics system 300 may be configured to present an external interface, to allow a connection to a 3rd party SCADA system or other control system. The external interface may be configured to use a standard SCADA protocol such as DNP, MODBUS over IP, and/or the like and may be configured to present device slave addresses and point maps such that the external SCADA system may poll or send commands to the cloud-based analytics system 300. The electric power data collection and analysis system 100 and/or the cloud-based analytics system 300 may parse SCADA messages, responding as needed. These commands and queries may be for data stored on the cloud-based analytics system 300, or require the cloud-based analytics system 300 to issue commands to various implementations of the electric power data collection and analysis system 100. For example, an operator may send a SCADA command to operate a component of the monitored element 400 from an outside system. This command may be received by the cloud-based analytics system 300, processed, and relayed to the electric power data collection and analysis system 100.

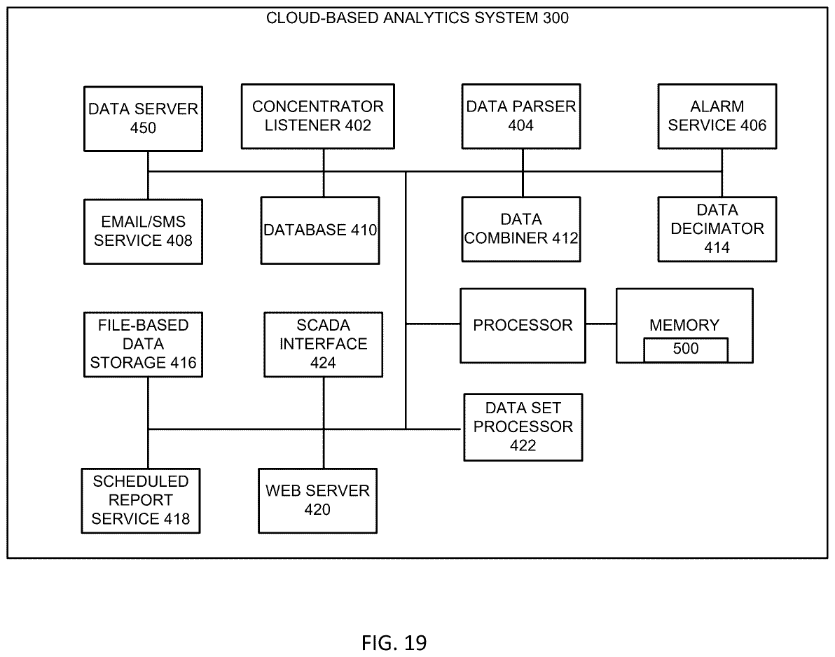

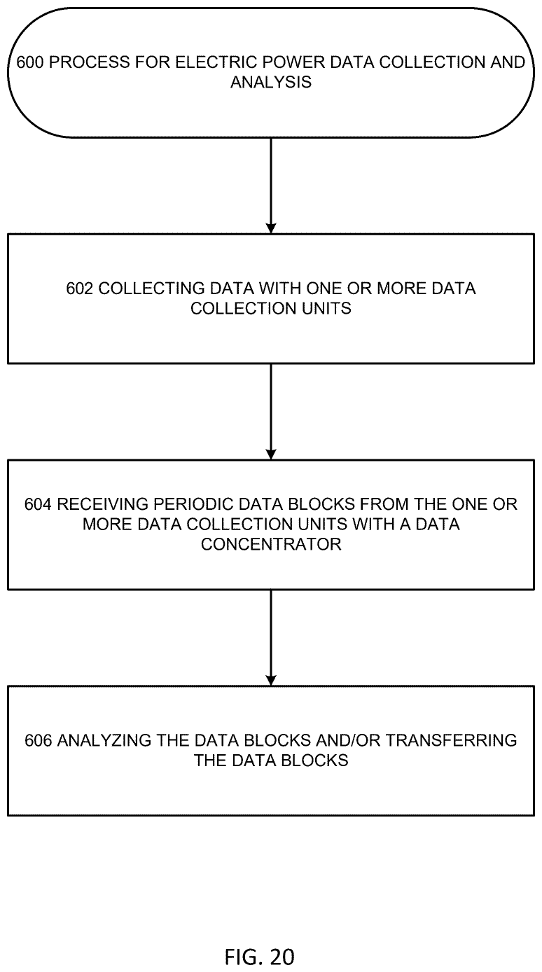

FIG. 20 illustrates a process for electric power data collection and analysis according to aspects of the disclosure.

In particular, FIG. 20 illustrates a process for electric power data collection and analysis 600 which may include any one or more the features described herein. The process for electric power data collection and analysis 600 may be implemented by any component of the electric power data collection and analysis system 100. The process for electric power data collection and analysis 600 may be implemented by software.

The process for electric power data collection and analysis 600 may include collecting data with one or more data collection units 602. In particular, the collecting data with one or more data collection units 602 may include collecting data as described herein by the one or more data collection units 102. For example, the collecting data with one or more data collection units 602 may include receiving an analog signal (line voltage, current, or the like), conditioning the signal, digitizing the signal, calculating a measurement of various factors (RMS, total harmonic distortion (THD), etc.), applying an averaging and conditioning of the measurement, and/or the like.

The process for electric power data collection and analysis 600 may include receiving periodic data blocks from the one or more data collection units with a data concentrator 604. In particular, the receiving periodic data blocks from the one or more data collection units with a data concentrator 604 may include receiving periodic data blocks from the one or more data collection units 102 with the data concentrator 150 as described herein.

The process for electric power data collection and analysis 600 may include analyzing the data blocks and/or transferring the data blocks 606. In particular, the analyzing the data blocks and/or transferring the data blocks 606 may include any of the analysis of the data blocks or transfer of the data blocks as described herein. For example, the analyzing the data blocks and/or transferring the data blocks 606 may include determining whether a trigger is met. If the trigger is met (yes), then analyzing the data blocks and/or transferring the data blocks 606 may send message to the cloud-based analytics system 300 or one or more other components as described herein.

Accordingly, the disclosure has disclosed a mechanism, system, and/or process to automatically identify common hookup errors, and optionally have the device correct for them in the device operation, before power quality metrics and recorded data is derived from them.

The following are a number of nonlimiting EXAMPLES of aspects of the disclosure.

One EXAMPLE: a process includes measuring an electrical parameter of a monitored element through at least one connection with at least one transducer. The process in addition includes determining whether the at least one connection to the monitored element is correct based on the electrical parameter with at least one processor. The process moreover includes outputting an error and potential fixes when the at least one connection to the monitored element is not correct with the at least one processor; and/or correcting electrical parameter data when the at least one connection to the monitored element is not correct with the at least one processor. The process also includes where the electrical parameter includes at least one of the following: voltage, current, phase, and/or polarity.

The above-noted EXAMPLE may further include any one or a combination of more than one of the following EXAMPLES:

The process of the above-noted EXAMPLE includes implementing an analog to digital sampling system, where the at least one transducer includes at least one of the following: a voltage transducer and/or a current transducer. The process of the above-noted EXAMPLE includes implementing a digital signal processor configured for data collection, pre-processing, and analytic operations. The process of the above-noted EXAMPLE includes: implementing a digital signal processor configured for data collection, pre-processing, and analytic operations; and implementing a second processor configured for data buffering and communication. The process of the above-noted EXAMPLE where the at least one processor is configured for data collection, pre-processing, analytic operations, data buffering, and communication. The process of the above-noted EXAMPLE includes implementing a data concentrator. The process of the above-noted EXAMPLE where the data concentrator is configured to send the electrical parameter data through a network to a data lake or cloud-based analytics system. The process of the above-noted EXAMPLE where the data concentrator is configured to accumulate data locally in a compressed format; and where the data concentrator is configured to periodically transfer the data to a removable storage device if the data concentrator is not connected to a network. The process of the above-noted EXAMPLE where the data concentrator is configured to receive raw waveform and other data from one or more data collection units; where the data concentrator is configured to provide timestamps; where the data concentrator is configured to compress the electrical parameter data in a format suitable for storage; and where the data concentrator is configured to store the electrical parameter data in an organized fashion for later retrieval. The process of the above-noted EXAMPLE where the data concentrator is configured to process data blocks from one or more data collection units for implementation in one of the following: a machine learning system and/or an artificial intelligence system. The process of the above-noted EXAMPLE includes implementing one or more data collection units, where the one or more data collection units are further configured to collect the electrical parameter data from the monitored element that includes at least one of the following: information associated with the monitored element, data associated with the monitored element, and measurements associated with the monitored element. The process of the above-noted EXAMPLE where the at least one processor is configured and/or operable to detect an increase in phase angle difference; where the at least one processor is configured and/or operable to simulate an effect of inverting a current transformer, swapping current transformer channels, or rolling all three current transformers by adding or subtracting 180 or 120 degrees appropriately; and where the at least one processor is configured and/or operable to determine a combination with a lowest total phase angle difference is a correct hookup and generate a correct fix to apply. The process of the above-noted EXAMPLE where the monitored element includes at least one of the following: an electrical substation, a solar farm, a wind farm, a Distributed Energy Resource (DER), a portion of a utility transmission infrastructure, a portion of a utility generation infrastructure, one or more circuits, one or more machines, and/or one or more components.

One EXAMPLE: an apparatus includes at least one transducer configured to measure an electrical parameter of a monitored element through at least one connection. The apparatus in addition includes at least one processor configured and/or operable to determine whether the at least one connection to the monitored element is correct based on the electrical parameter. The apparatus moreover includes the at least one processor configured and/or operable to output an error and potential fixes when the at least one connection to the monitored element is not correct; and/or the at least one processor configured and/or operable to correct electrical parameter data when the at least one connection to the monitored element is not correct. The apparatus also includes where the electrical parameter includes at least one of the following: voltage, current, phase, and/or polarity.

The above-noted EXAMPLE may further include any one or a combination of more than one of the following EXAMPLES:

The apparatus of the above-noted EXAMPLE includes an analog to digital sampling system, where the at least one transducer includes at least one of the following: a voltage transducer and/or a current transducer. The apparatus of the above-noted EXAMPLE includes a digital signal processor configured for data collection, pre-processing, and analytic operations. The apparatus of the above-noted EXAMPLE includes: a digital signal processor configured for data collection, pre-processing, and analytic operations; and a second processor configured for data buffering and communication. The apparatus of the above-noted EXAMPLE where the at least one processor is configured for data collection, pre-processing, analytic operations, data buffering, and communication. The apparatus of the above-noted EXAMPLE includes a data concentrator. The apparatus of the above-noted EXAMPLE where the data concentrator is configured to send the electrical parameter data through a network to a data lake or cloud-based analytics system. The apparatus of the above-noted EXAMPLE where the data concentrator is configured to accumulate data locally in a compressed format; and where the data concentrator is configured to periodically transfer the data to a removable storage device if the data concentrator is not connected to a network. The apparatus of the above-noted EXAMPLE where the data concentrator is configured to receive raw waveform and other data from one or more data collection units; where the data concentrator is configured to provide timestamps; where the data concentrator is configured to compress the electrical parameter data in a format suitable for storage; and where the data concentrator is configured to store the electrical parameter data in an organized fashion for later retrieval. The apparatus of the above-noted EXAMPLE where the data concentrator is configured to process data blocks from one or more data collection units for implementation in one of the following: a machine learning system and/or an artificial intelligence system. The apparatus of the above-noted EXAMPLE includes one or more data collection units, where the one or more data collection units are further configured to collect the electrical parameter data from the monitored element that includes at least one of the following: information associated with the monitored element, data associated with the monitored element, and measurements associated with the monitored element. The apparatus of the above-noted EXAMPLE where the at least one processor is configured and/or operable to detect an increase in phase angle difference; where the at least one processor is configured and/or operable to simulate an effect of inverting a current transformer, swapping current transformer channels, or rolling all three current transformers by adding or subtracting 180 or 120 degrees appropriately; and where the at least one processor is configured and/or operable to determine a combination with a lowest total phase angle difference is a correct hookup and generate a correct fix to apply. The apparatus of the above-noted EXAMPLE where the monitored element includes at least one of the following: an electrical substation, a solar farm, a wind farm, a Distributed Energy Resource (DER), a portion of a utility transmission infrastructure, a portion of a utility generation infrastructure, one or more circuits, one or more machines, and/or one or more components.

The artificial intelligence and/or machine learning may utilize any number of approaches including one or more of cybernetics and brain simulation, symbolic, cognitive simulation, logic-based, anti-logic, knowledge-based, sub-symbolic, embodied intelligence, computational intelligence and soft computing, machine learning and statistics, and the like.

Aspects of the disclosure may include communication channels that may be any type of wired or wireless electronic communications network, such as, e.g., a wired/wireless local area network (LAN), a wired/wireless personal area network (PAN), a wired/wireless home area network (HAN), a wired/wireless wide area network (WAN), a campus network, a metropolitan network, an enterprise private network, a virtual private network (VPN), an internetwork, a backbone network (BBN), a global area network (GAN), the Internet, an intranet, an extranet, an overlay network, Near field communication (NFC), a cellular telephone network, a Personal Communications Service (PCS), using known protocols such as the Global System for Mobile Communications (GSM), CDMA (Code-Division Multiple Access), GSM/EDGE and UMTS/HSPA network technologies, Long Term Evolution (LTE), 5G (5th generation mobile networks or 5th generation wireless systems), WiMAX, HSPA+, W-CDMA (Wideband Code-Division Multiple Access), CDMA2000 (also known as C2K or IMT Multi-Carrier (IMT-MC)), Wireless Fidelity (Wi-Fi), Bluetooth, and/or the like, and/or a combination of two or more thereof. The NFC standards cover communications protocols and data exchange formats, and are based on existing radio-frequency identification (RFID) standards including ISO/IEC 14443 and FeliCa. The standards include ISO/IEC 18092[3] and those defined by the NFC Forum.

Further in accordance with various aspects of the disclosure, the methods described herein are intended for operation with dedicated hardware implementations including, but not limited to, PCs, PDAs, semiconductors, application specific integrated circuits (ASIC), programmable logic arrays, cloud computing devices, and other hardware devices constructed to implement the methods described herein.

According to an example, the global navigation satellite system (GNSS) may include a device and/or system that may estimate its location based, at least in part, on signals received from space vehicles (SVs). In particular, such a device and/or system may obtain “pseudorange” measurements including approximations of distances between associated SVs and a navigation satellite receiver. In a particular example, such a pseudorange may be determined at a receiver that is capable of processing signals from one or more SVs as part of a Satellite Positioning System (SPS). Such an SPS may comprise, for example, a Global Positioning System (GPS), Galileo, Glonass, to name a few, or any SPS developed in the future. To determine its location, a satellite navigation receiver may obtain pseudorange measurements to three or more satellites as well as their positions at time of transmitting. Knowing the SV orbital parameters, these positions can be calculated for any point in time. A pseudorange measurement may then be determined based, at least in part, on the time a signal travels from an SV to the receiver, multiplied by the speed of light. While techniques described herein may be provided as implementations of location determination in GPS and/or Galileo types of SPS as specific illustrations according to particular examples, it should be understood that these techniques may also apply to other types of SPS, and that claimed subject matter is not limited in this respect.

It should also be noted that the software implementations of the disclosure as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to email or other self-contained information archive or set of archives is considered a distribution medium equivalent to a tangible storage medium. Accordingly, the disclosure is considered to include a tangible storage medium or distribution medium, as listed herein and including art-recognized equivalents and successor media, in which the software implementations herein are stored.

The term text message or SMS refers to “short message service” which is a text messaging service component of phone, web, or mobile communication systems. It uses standardized communications protocols to allow fixed line or mobile phone devices to exchange short text messages. SMS was originally designed as part of GSM, but is now available on a wide range of networks, including 3G, 4G, LTE, 5G networks or networks associated with the communication channel as defined herein. In other aspects, text message may include Multimedia Messaging Service (MMS), which is a standard way to send messages that include multimedia content to and from mobile phones. It extends the core SMS (Short Message Service) capability that allowed exchange of text messages only up to 160 characters in length. While the most popular use is to send photographs from camera-equipped handsets, it is also used as a method of delivering news and entertainment content including videos, pictures, text pages and ringtones. Of note is that MMS messages are delivered in a completely different way from SMS. The first step is for the sending device to encode the multimedia content in a fashion similar to sending a MIME e-mail (MIME content formats are defined in the MMS Message Encapsulation specification). The message is then forwarded to the carrier's MMS store and forward server, known as the MMSC (Multimedia Messaging Service Centre). If the receiver is on another carrier, the relay forwards the message to the recipient's carrier using the Internet.

In an aspect, the disclosure may be web-based. For example, a server may operate a web application to allow the disclosure to operate in conjunction with a database. The web application may be hosted in a browser-controlled environment (e.g., a Java applet and/or the like), coded in a browser-supported language (e.g., JavaScript combined with a browser-rendered markup language (e.g., Hyper Text Markup Language (HTML) and/or the like)) and/or the like such that any computer running a common web browser (e.g., Internet Explorer™, Firefox™, Chrome™, Safari™ or the like) may render the application executable. A web-based service may be more beneficial due to the ubiquity of web browsers and the convenience of using a web browser as a client (i.e., thin client). Further, with inherent support for cross-platform compatibility, the web application may be maintained and updated without distributing and installing software on each.

Additionally, the various aspects of the disclosure may be implemented in a non-generic computer implementation. Moreover, the various aspects of the disclosure set forth herein improve the functioning of the system as is apparent from the disclosure hereof. Furthermore, the various aspects of the disclosure involve computer hardware that it specifically programmed to solve the complex problem addressed by the disclosure. Accordingly, the various aspects of the disclosure improve the functioning of the system overall in its specific implementation to perform the process set forth by the disclosure and as defined by the claims.

Aspects of the disclosure may include a server executing an instance of an application or software configured to accept requests from a client and giving responses accordingly. The server may run on any computer including dedicated computers. The computer may include at least one processing element, typically a central processing unit (CPU), and some form of memory. The processing element may carry out arithmetic and logic operations, and a sequencing and control unit may change the order of operations in response to stored information. The server may include peripheral devices that may allow information to be retrieved from an external source, and the result of operations saved and retrieved. The server may operate within a client-server architecture. The server may perform some tasks on behalf of clients. The clients may connect to the server through the network on a communication channel as defined herein. The server may use memory with error detection and correction, redundant disks, redundant power supplies and so on.

The many features and advantages of the disclosure are apparent from the detailed specification, and, thus, it is intended by the appended claims to cover all such features and advantages of the disclosure which fall within the true spirit and scope of the disclosure. Further, since numerous modifications and variations will readily occur to those skilled in the art, it is not desired to limit the disclosure to the exact construction and operation illustrated and described, and, accordingly, all suitable modifications and equivalents may be resorted to that fall within the scope of the disclosure.

1. A process for implementing an apparatus for electric power data collection and analysis comprising:
measuring an electrical parameter of a monitored element through at least one connection with at least one transducer;
determining whether the at least one connection to the monitored element is correct based on the electrical parameter with at least one processor;
outputting an error and potential fixes when the at least one connection to the monitored element is not correct with the at least one processor; and/or correcting electrical parameter data when the at least one connection to the monitored element is not correct with the at least one processor,
wherein the electrical parameter comprises at least one of the following: voltage, current, phase, and/or polarity.

2. The process for implementing apparatus for electric power data collection and analysis of claim 1, further comprising implementing an analog to digital sampling system,
wherein the at least one transducer comprises at least one of the following: a voltage transducer and/or a current transducer.

3. The process for implementing apparatus for electric power data collection and analysis of claim 1, further comprising implementing a digital signal processor configured for data collection, pre-processing, and analytic operations.

4. The process for implementing apparatus for electric power data collection and analysis of claim 1, further comprising:
implementing a digital signal processor configured for data collection, pre-processing, and analytic operations; and
implementing a second processor configured for data buffering and communication.

5. The process for implementing apparatus for electric power data collection and analysis of claim 1, wherein the at least one processor is configured for data collection, pre-processing, analytic operations, data buffering, and communication.

6. The process for implementing apparatus for electric power data collection and analysis of claim 1, further comprising implementing a data concentrator.

7. The process for implementing apparatus for electric power data collection and analysis of claim 6, wherein the data concentrator is configured to send the electrical parameter data through a network to a data lake or cloud-based analytics system.

8. The process for implementing apparatus for electric power data collection and analysis of claim 6,
wherein the data concentrator is configured to accumulate data locally in a compressed format; and
wherein the data concentrator is configured to periodically transfer the data to a removable storage device if the data concentrator is not connected to a network.

9. The process for implementing apparatus for electric power data collection and analysis of claim 6,
wherein the data concentrator is configured to receive raw waveform and other data from one or more data collection units;
wherein the data concentrator is configured to provide timestamps;
wherein the data concentrator is configured to compress the electrical parameter data in a format suitable for storage; and
wherein the data concentrator is configured to store the electrical parameter data in an organized fashion for later retrieval.

10. The process for implementing apparatus for electric power data collection and analysis of claim 6, wherein the data concentrator is configured to process data blocks from one or more data collection units for implementation in one of the following: a machine learning system and/or an artificial intelligence system.

11. The process for implementing apparatus for electric power data collection and analysis of claim 1, further comprising implementing one or more data collection units,
wherein the one or more data collection units are further configured to collect the electrical parameter data from the monitored element that comprises at least one of the following: information associated with the monitored element, data associated with the monitored element, and measurements associated with the monitored element.

12. The process for implementing apparatus for electric power data collection and analysis of claim 1,
wherein the at least one processor is configured and/or operable to detect an increase in phase angle difference;
wherein the at least one processor is configured and/or operable to simulate an effect of inverting a current transformer, swapping current transformer channels, or rolling all three current transformers by adding or subtracting 180 or 120 degrees appropriately; and
wherein the at least one processor is configured and/or operable to determine a combination with a lowest total phase angle difference is a “correct” hookup and generate a correct fix to apply.

13. The process for implementing apparatus for electric power data collection and analysis of claim 1, wherein the monitored element comprises at least one of the following: an electrical substation, a solar farm, a wind farm, a Distributed Energy Resource (DER), a portion of a utility transmission infrastructure, a portion of a utility generation infrastructure, one or more circuits, one or more machines, and/or one or more components.

14. An apparatus for electric power data collection and analysis comprising:
at least one transducer configured to measure an electrical parameter of a monitored element through at least one connection;
at least one processor configured and/or operable to determine whether the at least one connection to the monitored element is correct based on the electrical parameter;
the at least one processor configured and/or operable to output an error and potential fixes when the at least one connection to the monitored element is not correct; and/or the at least one processor configured and/or operable to correct data when the at least one connection to the monitored element is not correct,
wherein the electrical parameter comprises at least one of the following:
voltage, current, phase, and/or polarity.

15. The apparatus for electric power data collection and analysis of claim 14, further comprising an analog to digital sampling system,
wherein the at least one transducer comprises at least one of the following: a voltage transducer and/or a current transducer.

16. The apparatus for electric power data collection and analysis of claim 14, further comprising a digital signal processor configured for data collection, pre-processing, and analytic operations.

17. The apparatus for electric power data collection and analysis of claim 14, further comprising:
a digital signal processor configured for data collection, pre-processing, and analytic operations; and
a second processor configured for data buffering and communication.

18. The apparatus for electric power data collection and analysis of claim 14, wherein the at least one processor is configured for data collection, pre-processing, analytic operations, data buffering, and communication.

19. The apparatus for electric power data collection and analysis of claim 14, further comprising a data concentrator.

20. The apparatus for electric power data collection and analysis of claim 19, wherein the data concentrator is configured to send the electrical parameter data through a network to a data lake or cloud-based analytics system.

21. The apparatus for electric power data collection and analysis of claim 19,
wherein the data concentrator is configured to accumulate data locally in a compressed format; and
wherein the data concentrator is configured to periodically transfer the data to a removable storage device if the data concentrator is not connected to a network.

22. The apparatus for electric power data collection and analysis of claim 19,
wherein the data concentrator is configured to receive raw waveform and other data from one or more data collection units;
wherein the data concentrator is configured to provide timestamps;
wherein the data concentrator is configured to compress the electrical parameter data in a format suitable for storage; and
wherein the data concentrator is configured to store the electrical parameter data in an organized fashion for later retrieval.

23. The apparatus for electric power data collection and analysis of claim 19, wherein the data concentrator is configured to process data blocks from one or more data collection units for implementation in one of the following: a machine learning system and/or an artificial intelligence system.

24. The apparatus for electric power data collection and analysis of claim 14, further comprising one or more data collection units,
wherein the one or more data collection units are further configured to collect the electrical parameter data from the monitored element that comprises at least one of the following: information associated with the monitored element, data associated with the monitored element, and measurements associated with the monitored element.

25. The apparatus for electric power data collection and analysis of claim 14,
wherein the at least one processor is configured and/or operable to detect an increase in phase angle difference;
wherein the at least one processor is configured and/or operable to simulate an effect of inverting a current transformer, swapping current transformer channels, or rolling all three current transformers by adding or subtracting 180 or 120 degrees appropriately; and
wherein the at least one processor is configured and/or operable to determine a combination with a lowest total phase angle difference is a “correct” hookup and generate a correct fix to apply.

26. The apparatus for electric power data collection and analysis of claim 14, wherein the monitored element comprises at least one of the following:
an electrical substation, a solar farm, a wind farm, a Distributed Energy Resource (DER), a portion of a utility transmission infrastructure, a portion of a utility generation infrastructure, one or more circuits, one or more machines, and/or one or more components.
